(19) United States
(12) Patent Application Publication
(10) Pub. No.: US 2026/0314436 A1
(43) Pub. Date: Oct. 8, 2026

(54) SEMICONDUCTOR PACKAGE WITH AN EMBEDDED INTERCONNECT AND A METHOD OF MAKING THE SAME

(71) Applicant: TEXAS INSTRUMENTS INCORPORATED, DALLAS, TX (US)

(72) Inventors: ENIS TUNCER, DALLAS, TX (US); RONGWEI ZHANG, PLANO, TX (US)

(21) Appl. No.: 19/171,651

(22) Filed: Apr. 7, 2025

(51) Int. Cl. H01L 23/495; H01L 21/48; H01L 23/00; H01L 23/31

(52) U.S. Cl. CPC H10W 70/421; H10W 70/04; H10W 74/131; H10W 72/865; H10W 90/736; H10W 90/756

(57) ABSTRACT

A semiconductor device can include a die and an interconnect structure attached to the die. The interconnect structure can include electrical interfaces and each electrical interface can include a contact pad located at a lower portion of the interconnect structure at a periphery thereof and a metal bonding segment located at an upper portion of the interconnect structure relative to the lower portion and in electrical contact with the die and the contact pad.

### TECHNICAL FIELD

This disclosure relates to semiconductor packaging. More particularly, this disclosure relates to a semiconductor package with an embedded interconnect and a method of making the same.

### BACKGROUND

A semiconductor device is an electronic component made from semiconductor material with controlled electrical conductivity. The term “semiconductor device” can refer to various types of electronics, including individual components, such as diodes, transistors, photonic devices and power devices, as well as integrated circuits (ICs).

### SUMMARY

A first example relates to a semiconductor package that can include a die and interconnect structure. The interconnect structure includes electrical interfaces, wherein each electrical interface can include a contact pad located at a lower portion of the interconnect structure at a periphery thereof and a metal bonding segment located at an upper portion of the interconnect structure relative to the lower portion and in electrical contact with the die and the contact pad.

A second example relates to a method that can include providing a wafer and attaching metal routing structures to a surface of the wafer. Each metal routing structure can include conductive routing features that extend through a body of each of the metal routing structures. The method can further include forming electrical connections between bonding locations of the wafer and conductive routing features, encapsulating the attached metal routing structures and the formed electrical connections with a mold while leaving a portion of the conductive routing features exposed, and singulating the intermediate wafer structure into semiconductor packages.

A third example relates to a method that can include forming a plurality of metal routing structures. Each metal routing structure can include conductive routing features that extend through a body of each of the metal routing structures. The method can further include securing the plurality of metal routing structures to a wafer, forming electrical connections between bonding locations of the wafer and the conductive routing features, encapsulating the attached metal routing structures and the formed electrical connections with a mold while leaving a portion of the conductive routing features exposed to provide an intermediate wafer structure and singulating the intermediate wafer structure into semiconductor packages. The exposed portion of each conductive routing feature forms a contact pad of a respective semiconductor package.

### BRIEF DESCRIPTION OF THE DRAWINGS

FIGS. 1A-1F illustrates example diagrams of various perspective views of a semiconductor package.

FIGS. 1G-L illustrates example diagrams of various perspective views of another semiconductor package.

FIGS. 2-14 illustrates stages of a method for forming a semiconductor device.

FIGS. 15-23 illustrates stages of a method for forming a metal routing structure for use in the fabrication of semiconductor devices.

FIGS. 24-34 illustrates stages of another method for forming a metal routing structure for use in the fabrication of semiconductor devices.

FIGS. 35A-35B illustrates an example of a diagram of a first wafer assembly.

FIGS. 36A-36B illustrates an example of a diagram of a second wafer assembly.

### DETAILED DESCRIPTION

This description relates to a semiconductor device and a method of making the same, where the semiconductor device can be approximately the same size as a die. In existing semiconductor packaging approaches, such as lead frame-based, wafer-level chip-scale packaging (WCSP), and substrate-based methods, device miniaturization, manufacturing efficiency, and input/output (I/O) density are constrained by design and process considerations. Lead frame and substrate-based packages, including ball grid array (BGA) and land grid array (LGA) solutions, need a minimum spacing between the die edge and package outline, resulting in a package size greater than the die itself. These substrate-based designs enable I/O connections beneath the die, for example, through routing but increase an overall package size due to additional layers needed for I/O routing and structural support, and such assemblies rely on complex, costly pick-and-place processes involving wire bonding or flip-chip techniques. In contrast, WCSP offers a more compact alternative by processing an entire wafer before singulation, eliminating separate die placement and assembly steps. However, WCSP is constrained by I/O density, the number of electrical input and output connections within a given package area, which depends on solder ball size (e.g., typically 150 to 350 microns) and pitch. Smaller pitches increase I/O density but, below a critical threshold, introduce reliability risks such as solder joint integrity issues, electromigration, and reduced manufacturing yield, often necessitating a greater die for additional solder ball placement and leading to inefficient die space allocation for I/O routing. Similarly, in wire-bonded molded packages, the package footprint exceeds die dimensions due to an extra space needed for bond pad placement, wire loop clearance, and encapsulation, which allows for proper wire bonding and mechanical protection but limits compactness. Consequently, achieving a compact package with high I/O density remains challenging, as spacing and encapsulation constraints dictate an arrangement of wire bonds and/or interconnects.

The methods disclosed herein provide semiconductor packages with dimensions substantially equivalent to a die itself, eliminating excessive spacing needed in lead frame and substrate-based solutions. Unlike existing approaches that rely on additional routing layers or encapsulation extending beyond a die footprint, the present technology as described herein can be used to integrate an interconnect structure within a package substrate. By employing whole-wafer processing, the described methods enhance manufacturing efficiency and simplify fabrication, curtailing the need for separate die assembly steps. Furthermore, the disclosed packaging techniques overcome the I/O density limitations of WCSP, where solder ball size and pitch constrain connection density. The interconnect structures described herein extend electrical pathways to a package edge, enabling high-density electrical connections without increasing a die size. The semiconductor package configuration described herein produces a compact, high-performance package with optimized space utilization, minimized material consumption, and improved manufacturability, rendering such a configuration particularly advantageous for compact electronic applications.

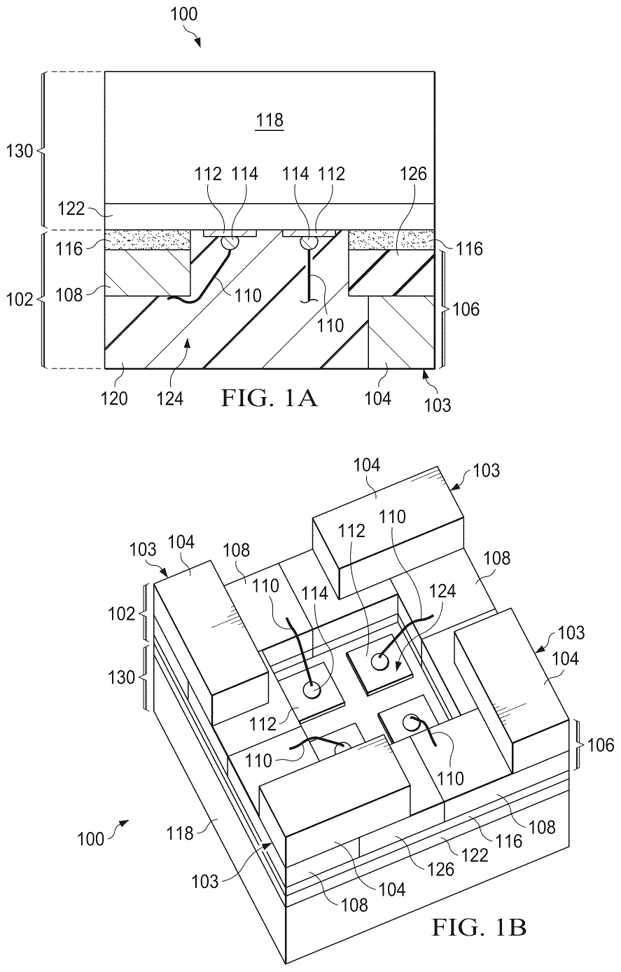

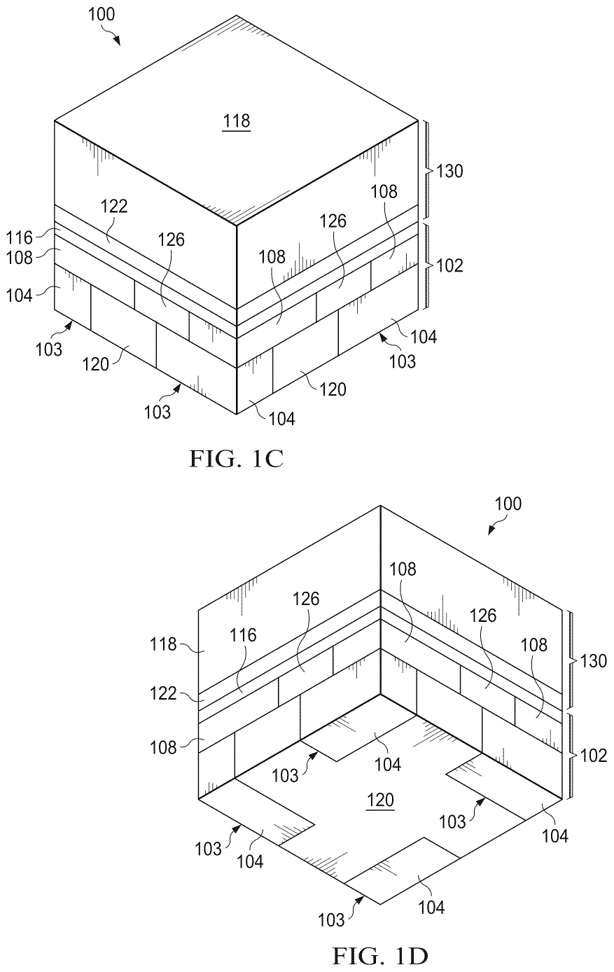

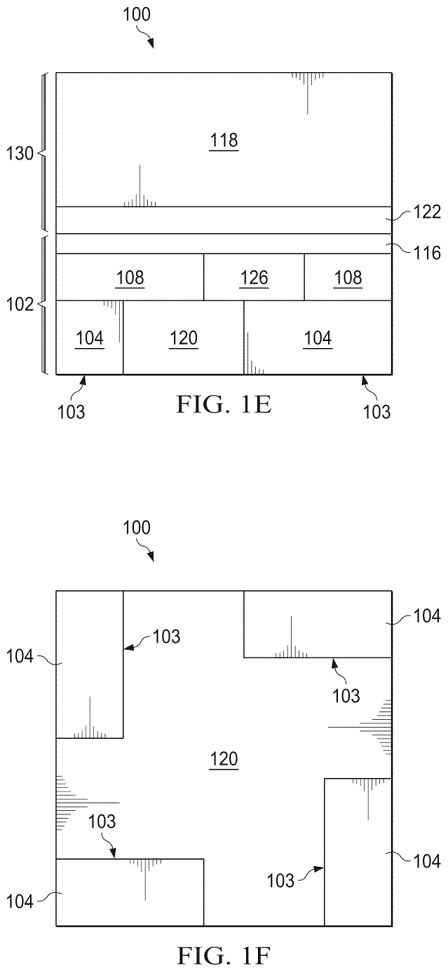

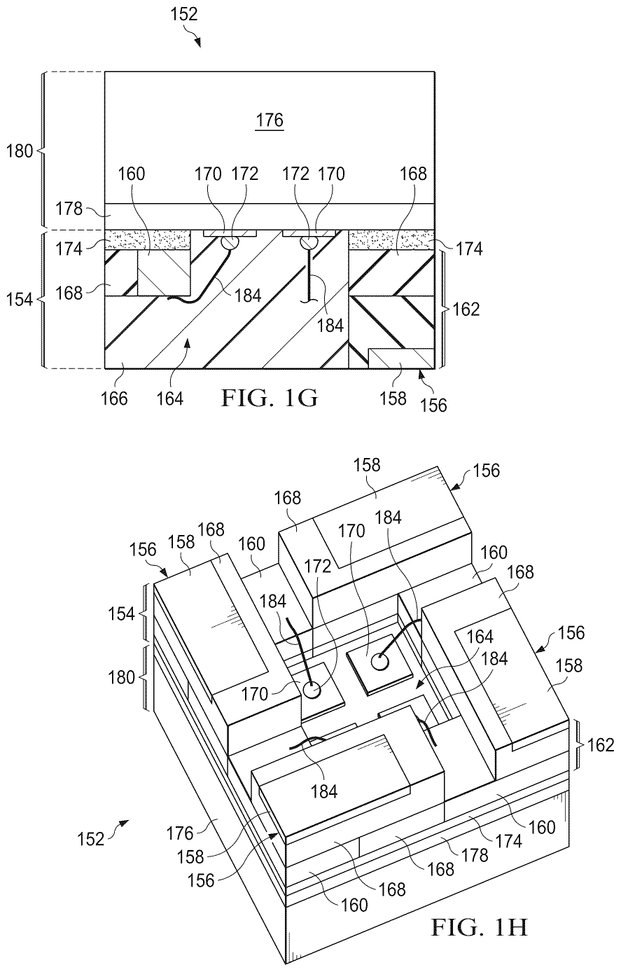

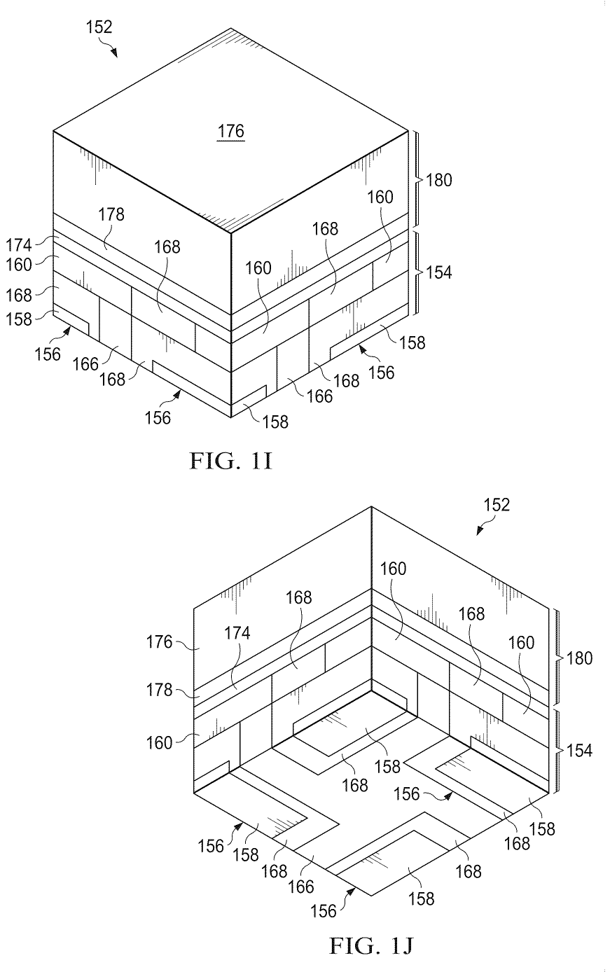

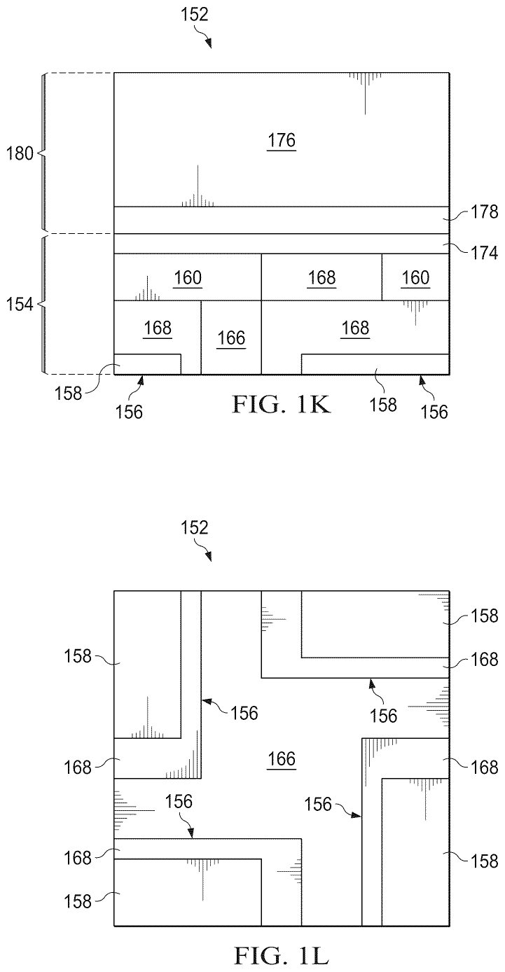

FIG. 1A illustrates a diagram of an example of a cross-sectional view of a semiconductor device 100 that includes a die 130 with an interconnect structure 102. In some examples, the die 130 can contain one or more functional circuits. For example, the die 130 can include (or house) multiple components (e.g., transistors, resistors, capacitors, etc.) at an active circuit region 122 that can be interconnected to perform a function (e.g., logic, amplification, etc.). In some examples, the die 130 can correspond to a discrete component (e.g., a single functional element, for example, a transistor, a diode, etc.). Thus, in some examples, the semiconductor device 100 can be a small outline package (SOP) type of semiconductor packaging device. The interconnect structure 102 can be integrated into the semiconductor device 100. The interconnect structure 102 includes electrical interfaces 103. The electrical interfaces 103 are conductive pathways for electrical signals, power and/or ground for use between the semiconductor device 100 (the active circuit region 122) and external components, such as printed circuit board (PCB) contacts or other circuitry. Thus, in some examples, the electrical interfaces 103 can be referred to as conductive routing features. The electrical interfaces 103 can be of a metal material, such as Copper (Cu), aluminum (Al), Gold (Au), or copper alloy. Each of the electrical interfaces 103 includes a contact pad 104, a vertical metal segment 106 (also referred to as a metal coupling segment, in some examples) and a wire bond segment 108 (also referred to as a metal bonding segment, in some examples). In some examples, the vertical metal segment 106 is a portion of the contact pad 104 and a portion of the wire bond segment 108.

As illustrated in FIG. 1A, each of the contact pads 104 is electrically coupled to a respective wire bond segment of wire bond segments 108. The contact pads 104 are electrical and mechanical interfaces for mounting the semiconductor device 100 onto a PCB or another electronic assembly. Each contact pad 104 can be located at a lower portion of the interconnect structure 102 at a periphery thereof. Each metal bonding segment (each wire bond segment 108) is located at an upper portion of the interconnect structure 102 relative to the lower portion at which the contact pads 104 are located. As illustrated in FIG. 1A, each metal bonding segment is in electrical contact with a respective die connection of die connections 112 (also referred to as bond pads or active circuitry region connection points, in some examples). Each metal coupling segment (e.g., each vertical metal segment 106) extends through a body of the interconnect structure 102 (e.g., from the lower portion to the upper portion) to electrically couple a respective metal bonding segment to a respective contact pad.

The interconnect structure 102 includes a cavity 124 (or opening) and a dielectric material 126. The cavity 124 is filled with (or includes) a molding 120 that is within (or surrounded by) the dielectric material 126, as illustrated in FIG. 1A. The cavity 124 is defined by an interior region within the interconnect structure 102, extending between the die 130 and the dielectric material 126. The cavity 124 is formed to accommodate wire bonds formed by wires 110, which establish electrical connections between the die connections 112 and the wire bond segments 108 of the electrical interfaces 103. The dielectric material 126 can include an epoxy-based resin, polyimide, benzocyclobutene (BCB), silicon dioxide (SiO₂), or an organic dielectric, such as Ajinomoto build-up film (ABF). The molding 120 can be a molding material, such as an epoxy-based molding compound (EMC), silicone, or polyimide, which provides structural integrity and environmental protection to the interconnect structure 102. The interconnect structure 102 includes wires 110 in the cavity 124. Respective first ends of the wires 110 are secured to corresponding die connections 112 by a bonded ball 114. Respective second ends of the wires 110 are connected to corresponding wire bond segments 108 of the electrical interfaces 103, establishing respective electrical pathways between the die connections 112 and the contact pads 104. The interconnect structure 102 further includes an adhesive material 116 to secure the interconnect structure 102 to the die 130 of the semiconductor device 100. The adhesive material 116 can be an epoxy-based adhesive, a polyimide adhesive, a thermosetting resin, a silicone-based adhesive, or another similar adhesive material.

As illustrated in FIG. 1A, the die 130 includes a substrate 118 (e.g., a portion of a wafer substrate) and the active circuit region 122. The substrate 118 can be a substrate material, such as a monocrystalline silicon wafer, silicon-on-insulator (SOI), gallium arsenide (GaAs), silicon carbide (SiC), or another semiconductor material used in semiconductor fabrication. The die connections 112 can be in electrical and physical contact with the active circuit region 122 such that electrical signals, power and/or ground connections from the active circuit region 122 can be transmitted through the die connections 112 to the interconnect structure 102 and subsequently to external components, such as a PCB or system. The interconnect structure 102 can be located beneath the die 130 so that the active circuit region 122 is in electrical and physical contact with the electrical interfaces 103 via corresponding bond-pad wire connections, as illustrated in FIG. 1A.

FIGS. 1B-1F illustrates various perspective views of the semiconductor device 100 of FIG. 1A. Thus, for clarity and brevity purposes, similar reference numerals are used in FIGS. 1B-1F as used in FIG. 1A to denote corresponding drawing elements. For example, FIG. 1B illustrates a first perspective of the semiconductor device 100 but with the molding 120 omitted to reveal the cavity 124 (or the opening) and internal wire connections therein. As illustrated in FIG. 1B, the interconnect structure 102 is attached to the die 130, with the cavity 124 exposed to show bonding of the wires 110 to the wire bond segments 108 and the die connections 112. Each wire 110 has a first end secured to a corresponding die connection 112 via the bonded ball 114 and a second end connected to a respective wire bond segment 108 of the electrical interfaces 103. The dielectric material 126 can at least partially surround the cavity 124. As illustrated, vertical metal segments 106 can extend through the interconnect structure 102. In some examples, the vertical metal segment 106 can be a portion of the contact pad 104 and a portion of the wire bond segment 108. The adhesive material 116 is also illustrated in FIG. 1B, securing the interconnect structure 102 to the substrate 118 of the die 130, with the active circuit region 122 positioned above the substrate 118.

In some examples, as illustrated in FIG. 1B, each die connection 112 can be located on a surface of the die 130. Each die connection 112 can be positioned at a bottom of the cavity 124. The cavity 124 can be an open region within the interconnect structure 102 that can be bound by at least the surface of the die 130 at the bottom. In yet some examples, as illustrated in FIG. 1B, contact pads 104 of the electrical interfaces 103 can be positioned at corners of the interconnect structure 102 (the semiconductor device 100). The interconnect structure 102 can have a rectangular footprint defined by four peripheral edges, each corner being an intersection of two adjacent peripheral edges, such that each contact pad 104 can be located at a respective corner of the lower portion of the interconnect structure 102, providing electrical and mechanical interfaces at the corners of the semiconductor device 100 for external connection (e.g., to the PCB).

FIG. 1C illustrates a second perspective view of the semiconductor device 100, providing a three-dimensional (3-D) representation of an assembled package. The second perspective illustrates external characteristics (or structure) of the semiconductor device 100, including the die 130 positioned on the interconnect structure 102. As illustrated in the second perspective view, the contact pads 104 can be located at the periphery of the lower portion of the interconnect structure 102, functioning as external electrical and mechanical interfaces. As illustrated in FIG. 1C, the semiconductor device 100 can be referred to as a compact semiconductor device (or package) due to an integration of the interconnect structure 102 into a package itself, which positions the contact pads 104 within the periphery of the semiconductor device 100. Because the interconnect structure 102 does not extend beyond the edges of the die 130, the semiconductor device 100 maintains a compact package design without a need for additional spacing beyond a die area. Accordingly, the overall footprint of the semiconductor device 100 remains about within the dimensions of the die 130 (e.g., die footprint).

FIG. 1D illustrates a third perspective view of the semiconductor device 100, oriented to show a bottom side of the semiconductor device 100. As illustrated in FIG. 1D, the contact pads 104 are located at the periphery of the lower portion of the interconnect structure 102 (the semiconductor device 100), which are exposed for mounting onto the PCB or other electronic assembly. The molding 120 fills the cavity 124 (e.g., as illustrated in FIG. 1B) to provide structural support and encapsulate internal wire connections to protect these connections from environmental factors.

FIG. 1E illustrates a side view of the semiconductor device 100, corresponding to a profile perspective of the semiconductor device 100. The die 130 is shown atop the interconnect structure 102, with the adhesive material 116 securing the two components to each other. The molding 120 fills the cavity 124 (e.g., as illustrated in FIG. 1B) within the interconnect structure 102, surrounded by the dielectric material 126. The contact pads 104 are positioned at the periphery of the lower portion of the interconnect structure 102 (the semiconductor device 100), while the wire bond segments 108 and vertical metal segments 106 are embedded within a body of the semiconductor device 100, electrically coupling (or linking) the die connections 112 to the contact pads 104, as shown in FIG. 1A.

FIG. 1F illustrates a bottom view of the semiconductor device 100, showing an underside of the semiconductor device 100, in some examples, when the semiconductor device 100 is mounted onto a PCB. As illustrated in FIG. 1F, the contact pads 104 are located or positioned at the periphery of the lower portion of the interconnect structure 102 (the semiconductor device 100), arranged to facilitate electrical and mechanical connection to external circuitry (e.g., the PCB). The molding 120 forms a portion of a bottom surface of the semiconductor device 100, with the contact pads 104 providing the conductive interfaces and corresponding to a remaining portion of the bottom surface of the semiconductor device 100. As illustrated in FIG. 1F, the contact pads 104 are positioned within a semiconductor package and allow for high-density I/O connectivity without increasing the overall package size beyond the dimensions (e.g., footprint area) of the die 130.

FIG. 1G illustrates a diagram of another example of a cross-sectional view of a semiconductor device 152 with a die 180 and an interconnect structure 154. The semiconductor device 152 can be an SOP type of semiconductor packaging device. In some examples, the die 180 can contain one or more functional circuits. For example, the die 180 can contain (or house) multiple components (e.g., transistors, resistors, capacitors, etc.) at an active circuit region 178 that can be interconnected to perform a function (e.g., logic, amplification, etc.). In some examples, the die 180 can correspond to a discrete component (e.g., a single functional element, for example, a transistor, a diode, etc.). In some examples, the die 180 is the die 130 of FIG. 1A. The interconnect structure 154 can be integrated into the semiconductor device 152. The interconnect structure 154 includes electrical interfaces 156. The electrical interfaces 156 are conductive pathways for electrical signals, power and/or ground for use between the semiconductor device 152 (the active circuit region 178) and external components, such as PCB contacts, or other circuitry. Thus, in some examples, the electrical interfaces 156 can be referred to as conductive routing features. The electrical interfaces 156 can be a metal material, such as described herein. Each of the electrical interfaces 156 includes a contact pad 158, a wire bond segment 160 (also referred to as a metal bonding segment, in some examples) and a metal coupling segment 162, which, in some instances can be a conductive via.

As illustrated in FIG. 1G, each of the contact pads 158 can be electrically coupled by corresponding metal coupling segments 162 to a respective wire bond segment of the wire bond segments 160. The contact pads 158 are electrical and mechanical interfaces for mounting the semiconductor device 152 onto a PCB or another electronic assembly. Each contact pad 158 can be located at a lower portion of the interconnect structure 154 at a periphery thereof. Each metal bonding segment (each wire bond segment 160) can be located at an upper portion of the interconnect structure 154 relative to the lower portion at which the contact pads 158 can be located. As illustrated in FIG. 1G, each metal bonding segment is in electrical contact with a respective die connection of the die connections 170 (also referred to as bond pads, active circuit region connection points or bonding locations, in some examples). Each metal coupling segment (162 can extend through a body of the interconnect structure 154 (e.g., from the lower portion to the upper portion) to electrically couple a respective metal bonding segment to a respective contact pad.

The interconnect structure 154 includes a cavity 164 (or opening) and dielectric material 168. The cavity 164 is defined by an interior region within the interconnect structure 154, extending between the die 180 and the dielectric material 168. The cavity 164 is formed to accommodate wire bonds formed by wires 184, which establish electrical connections between the die connections 170 and the wire bond segments 160 of the electrical interfaces 156. The cavity 164 is filled with (or includes) a molding 166 that is within (or surrounded by) the dielectric material 168, as illustrated in FIG. 1G. The metal coupling segments 162 extend through the dielectric material 168 to couple a respective one of the contact pads 158 to a respective wire bond segment of the wire bond segments 160. The dielectric material 168 can be of similar or same composition as the dielectric material 126 of FIG. 1A. The molding 166 can be a molding material, such as described herein and can provide structural integrity and environmental protection to the interconnect structure 154. The interconnect structure 154 includes wires 184 in the cavity 164. Respective first ends of the wires 184 are secured to corresponding die connections 170 by a bonded ball 172. Respective second ends of the wires 184 are connected to corresponding wire bond segments 160 of the electrical interfaces 156, establishing respective electrical pathways between the die connections 170 and the contact pads 158. The interconnect structure 154 further includes an adhesive material 174 to secure the interconnect structure 154 to the die 180 of the semiconductor device 152. The adhesive material 174 can be of similar or same composition as the adhesive material 116 of FIG. 1A.

As illustrated in FIG. 1G, the die 180 includes a substrate 176 (e.g., a portion of a wafer substrate) and the active circuit region 178. The die connections 170 can be in electrical and physical contact with the active circuit region 178 such that electrical signals, power and/or ground connections from the active circuit region 178 can be provided through the die connections 170 to the interconnect structure 154 and subsequently to external components, such as a PCB system. The substrate 176 can be a substrate material, such as described herein. The interconnect structure 154 can be located beneath the substrate 176 so that the active circuit region 178 is in electrical and physical contact with the electrical interfaces 156 via corresponding bond-pad wire connections.

FIGS. 1H-1L illustrates various perspective views of the semiconductor device 152 of FIG. 1AB. Thus, for clarity and brevity purposes, similar reference numerals are used in FIGS. 1H-1L as used in FIG. 1G to denote corresponding drawing elements. For example, FIG. 1H illustrates a first perspective view of the semiconductor device 152, but with the molding 166 omitted to reveal the cavity 164 (or the opening) and internal wire connections therein. As illustrated in FIG. 1H, the interconnect structure 154 is shown attached to the die 180, with the cavity 164 exposed to show a bonding of the wires 184 to the wire bond segments 160 and the die connections 170. Each wire 184 is depicted with a first end secured to a corresponding die connection 170 via the bonded ball 172 and a second end connected to a respective wire bond segment 160 of the electrical interfaces 156. The metal coupling segments 162 can extend through the interconnect structure 154 to connect the wire bond segments 160 to the contact pads 158 at the periphery of the lower portion of the interconnect structure 154 (the semiconductor device 152). The adhesive material 174 is also illustrated in FIG. 1H, securing the interconnect structure 154 to the substrate 176 of the die 180, with the active circuit region 178 positioned above the substrate 176.

In some examples, as illustrated in FIG. 1H, each die connection 170 can be located on a surface of the die 180. Each die connection 170 can be positioned at a bottom of the cavity 164. The cavity 164 can be an open region within the interconnect structure 154 that can be bound by at least the surface of the die 180 at the bottom. In yet some examples, as illustrated in FIG. 1H, contact pads 158 of the electrical interfaces 156 can be positioned at corners of the interconnect structure 154 (the semiconductor device 152). The interconnect structure 154 can have a rectangular footprint defined by four peripheral edges, each corner being an intersection of two adjacent peripheral edges, such that each contact pad 158 can be located at a respective corner of the lower portion of the interconnect structure 154, providing electrical and mechanical interfaces at the corners of the semiconductor device 152 for external connection (e.g., to the PCB).

FIG. 1I illustrates a second perspective view of the semiconductor device 152, providing a 3D representation of an assembled package. The second perspective illustrates external characteristics of the semiconductor device 152, including the die 180 positioned on the interconnect structure 154. As illustrated in FIG. 1I, the contact pads 158 are located at the periphery of the lower portion of the interconnect structure 154 (the semiconductor device 152), serving as external electrical and mechanical interfaces. As illustrated in FIG. 1I, the semiconductor device 152 can be referred to as a compact semiconductor device (or package) due to an integration of the interconnect structure 154 into a package itself, which positions the contact pads 158 within the periphery of the semiconductor device 152. Because the interconnect structure 154 does not extend beyond the edges of the die 180, the semiconductor device 152 maintains a compact package design without a need for additional spacing beyond a die area. Accordingly, the overall footprint of the semiconductor device 152 remains about within the dimensions of the die 180 (e.g., die footprint).

FIG. 1J illustrates a third perspective view of the semiconductor device 152, oriented to show a bottom side of the semiconductor device 152. As illustrated in FIG. 1J, the contact pads 158 are located at the periphery of the lower portion of the interconnect structure 154 (the semiconductor device 152), which are exposed for mounting onto the PCB or other electronic assembly. The molding 166 fills the cavity 164 (e.g., as illustrated in FIG. 1H) to provide structural support and encapsulate internal wire connections to protect these connections from environmental factors.

FIG. 1K illustrates a side view of the semiconductor device 152, corresponding to a profile perspective of the semiconductor device 152. The die 180 is shown atop the interconnect structure 154, with the adhesive material 174 securing the two components to each other. The molding 166 fills the cavity 164 (e.g., as illustrated in FIG. 1H) within the interconnect structure 154, surrounded by the dielectric material 168. The contact pads 158 can be positioned at the periphery of the lower portion of the interconnect structure 154 (the semiconductor device 152), while the wire bond segments 160 and metal coupling segments 162 are embedded within a body of the semiconductor device 152, electrically coupling (or linking) the die connections 170 to the contact pads 158, as shown in FIG. 1G.

FIG. 1L illustrates a bottom view of the semiconductor device 152, showing an underside of the semiconductor device 152, in some examples, when the semiconductor device 152 is mounted onto a PCB. As illustrated in FIG. 1L, the contact pads 158 are located at the periphery of the lower portion of the interconnect structure 154 (the semiconductor device 152), arranged to facilitate electrical and mechanical connection to external circuitry (e.g., the PCB). The molding 166 forms a portion of a bottom surface of the semiconductor device 152, with the contact pads 158 providing the conductive interfaces and corresponding to a remaining portion of the bottom surface of the semiconductor device 152. As illustrated in FIG. 1L, the contact pads 158 are positioned within a semiconductor package and allow for high-density I/O connectivity without increasing the overall package size beyond the dimensions (e.g., footprint area) of the die 180.

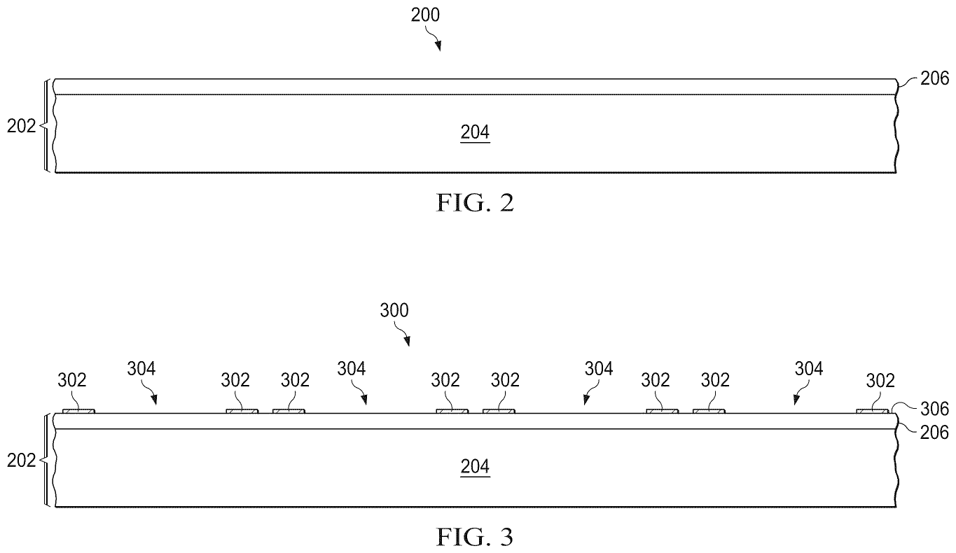

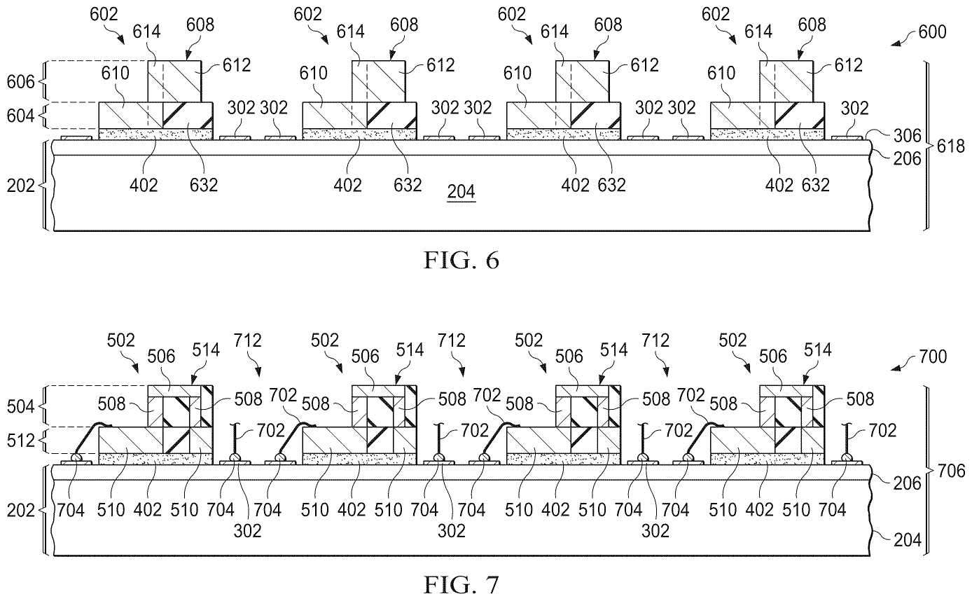

FIGS. 2-14 illustrate stages of a method for fabricating (e.g., assembling) a semiconductor package, such as the semiconductor device 100 of FIG. 1A or the semiconductor device 152 of FIG. 1G. The fabrication stages as illustrated in FIGS. 2-14 depict cross-sectional side views of a semiconductor package assembly process, such as for forming the semiconductor device 100 of FIG. 1A or the semiconductor device 152 of FIG. 1G. These cross-sectional views represent a single plane through one or more wafer structures (e.g., intermediate wafer structure 518 of FIG. 5 or intermediate wafer structure 618 of FIG. 6, for example) and, accordingly, illustrate a subset of contact pads (e.g., the contact pads 104 of FIG. 1A or the contact pads 158 of FIG. 1G), metal coupling segments (e.g., metal coupling segments 162), and wire bond segments (e.g., wire bond segments 108 or 160) that can be present in one or more interconnect structures (e.g., the interconnect structure 102 of FIG. 1A or the interconnect structure 154 of FIG. 1G). For a complete illustration of all contact pads and related features positioned along a periphery of interconnect structures, additional views are provided, including the cross-sectional view of FIG. 1B and the perspective views of FIGS. 1C-1F and 1I-1L, which illustrate electrical interfaces of an assembled semiconductor package.

As illustrated in FIG. 2, at a first stage 200, a wafer 202 can be prepared. In yet some examples, at the first stage 200, the wafer 202 can be received or provided after front-end fabrication. Thus, in some examples, the method for fabricating the semiconductor package according to the example method can be part of a wafer back-end fabrication process. The wafer 202 includes a substrate 204, which can be a base material for the wafer 202 and can be a foundation for subsequent fabrication steps, as described herein. The substrate 204 can be a silicon substrate. In yet some examples, the substrate 204 is referred to as a wafer substrate. The substrate 204 (or the wafer 202) includes an active silicon layer 206, which can be a region or portion (e.g., an upper portion) of the substrate 204 that can contain one or more circuit components (e.g., individual components or a combination of components). In some examples, the active silicon layer 206 can correspond to the active circuit region 122 of FIG. 1A or the active circuit region 178 of FIG. 1G.

At a second stage 300, as illustrated in FIG. 3, bond pads 302 can be formed on a surface of the wafer 202. In some examples, the bond pads 302 can be referred to as die connections, active circuit region connection points, or bonding locations (wafer bonding locations). Thus, in some examples, the bond pads 302 can correspond to the die connections 112 of FIG. 1A or the die connections 170 of FIG. 1G. The bond pads 302 can be selectively formed on the surface of the wafer 202 to allow for the securement of corresponding metal routing structures to the wafer 202. The bond pads 302 can be selectively formed on the surface of the wafer 202 such that the bond pads 302 align with specified contact points for interconnect structure attachment while allowing for proper spacing to prevent electrical shorting. In some examples, the bond pads 302 can be formed using a deposition and patterning process, such as physical vapor deposition (PVD) followed by photolithographic patterning and etching. The bond pads 302 can have a defined height relative to a wafer surface 306 (or a top wafer surface) of the wafer 202. The bond pads 302 can be formed such that at least some of the bond pads 302 result or form bond pad pairs (or bond pad neighbors). Openings 304 can be formed next to a bond pad or between neighboring bond pads of the bond pads 302 at the second stage 300, as illustrated in FIG. 3. These openings 304 provide access to regions on the wafer surface 306 that remain exposed after bond pad formation and thus can be referred to as non-metallized regions of the wafer surface 306. By contrast, areas of the wafer surface 306 on which the bond pads 302 are formed can be referred to as metallized regions of the wafer surface 306.

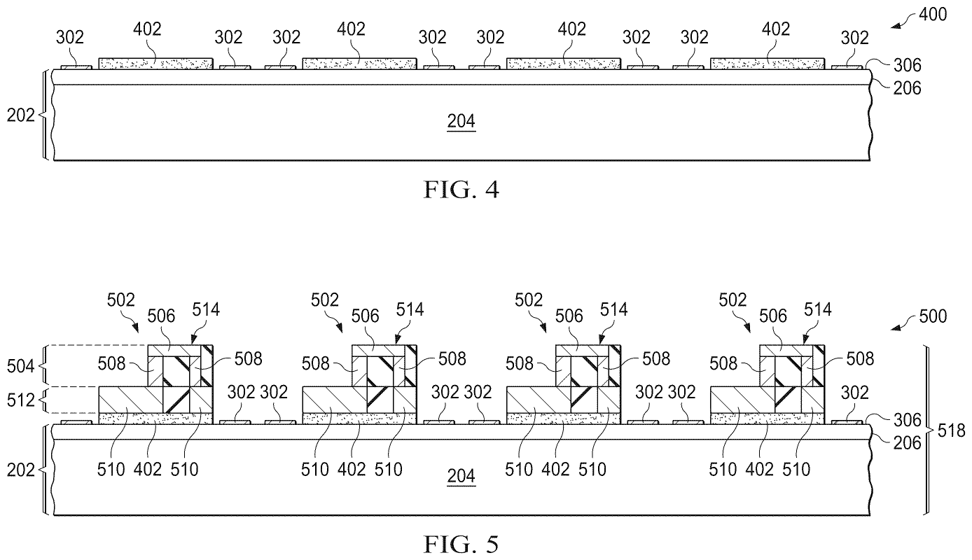

In some implementations, the method proceeds from the second stage 300 to a third stage 400, as illustrated in FIG. 4. At the third stage 400, an adhesive material 402 is deposited into the openings 304 and onto the non-metallized regions of the wafer surface 306. The adhesive material 402 can be deposited using a dispensing process, such as stencil printing, screen printing or spin coating. In some examples, the adhesive material 402 can correspond to the adhesive material 116 of FIG. 1A or the adhesive material 174 of FIG. 1G. The adhesive material 402 is applied onto the non-metallized regions of the wafer surface 306 within the openings 304 so that exposed portions of the wafer surface 306 in these regions are at least partially covered.

In a first example, after the third stage 400, a metal routing structure (e.g., a metal routing structure 502 of FIG. 5) can be attached to the adhesive material 402. Thus, in the first example, metal routing structures can be used that have been fabricated without the adhesive material 402, as described herein. The semiconductor devices described herein, such as the semiconductor device 100 of FIG. 1A and the semiconductor device 152 of FIG. 1G, incorporates an interconnect structure (e.g., interconnect structure 102 and interconnect structure 154), which can include one or more metal routing structures (e.g., one or more metal routing structures 502 of FIG. 5 or one or more metal routing structures 602 of FIG. 6). For example, the metal routing structures 502 and 602, as illustrated in FIGS. 5 and 6, respectively, function as components that can be integrated into a wafer assembly process.

As illustrated in FIG. 5, each metal routing structure 502 includes a conductive routing feature 514. Each conductive routing feature 514 includes a top metal segment 506 located at an upper portion 504 of each metal routing structure 502, a metal coupling segment 508 and an edge metal segment 510. The top metal segment 506 is positioned at an upper portion 504 of each metal routing structure 502, while the metal coupling segment 508 can extend vertically through the body of the metal routing structure 502, coupling the top metal segment 506 to the edge metal segment 510. The edge metal segment 510 is positioned at a lower portion 512 of the metal routing structure 502 and protrudes outward from an inner body of the lower portion 512 toward a periphery (or edge) of the metal routing structure 502.

As illustrated in FIG. 6, each metal routing structure 602 includes a conductive routing feature 608. Each conductive routing feature 608 includes a top metal segment 612 located at an upper portion 606 of each metal routing structure 602, a vertical metal segment 614 (also referred to as a metal coupling segment), and an edge metal segment 610. The top metal segment 612 is located at an upper portion 606 of each metal routing structure 602, while the vertical metal segment 614 is positioned along an edge of the upper portion 606. In some examples, the vertical metal segment 614 electrically couples the top metal segment 612 to the edge metal segment 610, which is positioned at a lower portion 604 of each metal routing structure 602. In some examples, the vertical metal segment 614 is a portion of the top metal segment 612 and a portion of the edge metal segment 610. The edge metal segment 610 can extend outward from an inner body of the lower portion 604 toward a periphery (or edge) of the metal routing structure 602.

For example, after the third stage 400, the method proceeds to a fourth stage 500, at which the metal routing structures 502 (in examples where such structures are produced without the adhesive material 402) are attached to the wafer 202, resulting in an intermediate wafer structure 518, as illustrated in FIG. 5. In the first example, when attaching the metal routing structures 502, the metal routing structures 502 can be placed onto corresponding adhesive material within the openings 304 and a curing process, such as thermal curing, ultraviolet (UV) curing or pressure-assisted curing, can be used to solidify the adhesive material 402 and secure the metal routing structures 502 to the wafer 202 (the wafer surface 306).

In some implementations, the method can proceed from the second stage 300 to the fourth stage 500, bypassing the third stage 400. In such cases, referred to herein as a second example, the metal routing structures 502 can be fabricated with the adhesive material 402 and are attached to the wafer surface 306 by corresponding adhesive materials. A subsequent curing process, such as thermal curing, UV curing, or pressure-assisted curing, can be applied to solidify the adhesive material 402 when positioned on the wafer surface 306 at respective openings 304 to form a secure bond between the metal routing structures 502 and the non-metallized regions of the wafer surface 306 of the wafer 202 via the adhesive material 402, resulting in the intermediate wafer structure 518, as illustrated in FIG. 5.

In some implementations, such as a third example, the method proceeds to a fifth stage 600 from the third stage 400. In such cases, metal routing structures 602 that do not include pre-applied adhesive material are placed onto the adhesive material 402 and a curing process, such as thermal curing, UV curing or pressure-assisted curing, can be applied to solidify the adhesive material 402 and secure the metal routing structures 602 in place, resulting in an intermediate wafer structure 618, as illustrated in FIG. 6. In other implementations, such as a fourth example, the method can proceed from the second stage 300 to the fifth stage 600, bypassing the third stage 400. In these cases, the metal routing structures 602 can be fabricated with the adhesive material 402 and positioned onto the non-metallized regions of the wafer surface 306. A subsequent curing process can be applied to solidify the adhesive material 402, thereby securing the metal routing structures 602 to the wafer surface 306, resulting in the intermediate wafer structure 618, as illustrated in FIG. 6.

In some examples, the method proceeds to a sixth stage 700 from the fourth stage 500, where wire bonding is performed. The wire bonding process establishes electrical connections between the bond pads 302 and the edge metal segments 510 of each metal routing structure 502, as illustrated in FIG. 7. Thus, at the sixth stage 700, wires 702 are used to couple the edge metal segments 510 of each metal routing structure 502 to a corresponding bond pad of the bond pads 302. During wire bonding, a first end of each of the wires 702 undergoes ball bonding, where a ball bond can be formed at a tip of a wire (e.g., using an electronic flame-off (EFO) process). The ball bond is then pressed onto the corresponding bond pad of the bond pads 302 (e.g., using thermosonic bonding, which applies a combination of heat, ultrasonic energy and pressure) to form an electrical connection corresponding to a bonded ball 704. After the first end of each wire 702 is secured to one of the bond pads 302 by the bonded ball 704, each of the wires 702 is looped to a corresponding edge metal segment 510 of the metal routing structure 502, where a second end of the wires 702 is attached via a wedge bond or stitch bond to an exposed surface of the edge metal segment 510. The wire bonding process can be repeated for each metal routing structure 502 to form electrical connections between the bond pads 302 and the metal routing structures 502, resulting in an intermediate wafer structure 706, as illustrated in FIG. 7.

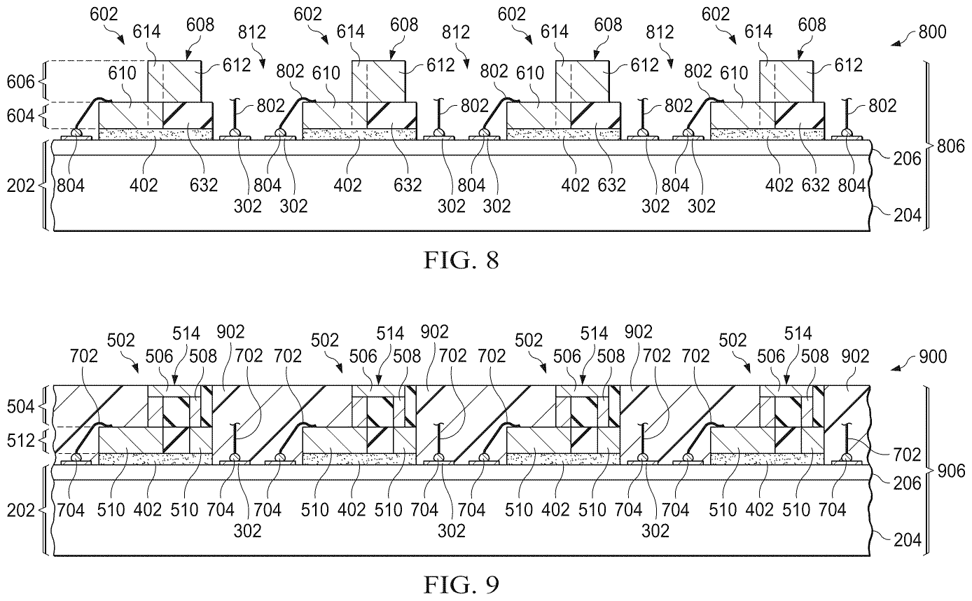

In some examples, the method proceeds to a seventh stage 800 from the fifth stage 600, where wire bonding is performed. The wire bonding process establishes electrical connections between the bond pads 302 and the edge metal segments 610 of each metal routing structure 502, as illustrated in FIG. 8. Thus, at the seventh stage 800, wires 802 are used to couple edge metal segments 610 of each metal routing structure 602 to a corresponding bond pad of the bond pads 302. During wire bonding, a first end of each of the wires 802 undergoes ball bonding, where a ball bond can be formed at a tip of a wire. The ball bond is then pressed onto a corresponding bond pad of the bond pads 302 to form an electrical connection corresponding to a bonded ball 804. After the first end of each wire 802 is secured to one of the bond pads 302 by the bonded ball 804, each of the wires 802 is looped to an edge metal segment 610 of the metal routing structure 602, where a second end of the wires 802 is attached via a wedge bond or stitch bond to an exposed surface of the edge metal segment 610. The wire bonding process can be repeated for each metal routing structure 602 to form electrical connections between the bond pads 302 and the metal routing structures 602, resulting in an intermediate wafer structure 806, as illustrated in FIG. 8.

In some examples, neighboring or adjacent metal routing structures define a cavity 712, as illustrated in FIG. 7, or a cavity 812, as illustrated in FIG. 8. These cavities 712, 812 are an open region for wire bonding. In yet some examples, a respective cavity 712, 812 can correspond to the cavity 124 of FIG. 1A-1B, or the cavity 164 of FIGS. 1G-1H. Within each cavity 712, 812, wires (e.g., the wires 702, 802 of FIGS. 7-8, respectively) extend between the bond pads 302 and corresponding edge metal segments 510, 610. This configuration ensures that wire bonding is performed before the cavity is enclosed by encapsulation, preventing interference from molding material during wire bonding. The cavity 812 minimizes package footprint by allowing for wire bonds to be integrated within an interconnect structure itself. In some examples, the wire bonding at the sixth and seventh stages 700-800 can be performed using a wire bonder, which can position and attach wires by applying heat, pressure, and ultrasonic energy to form electrical connections between bond pads and the edge metal segments of the metal routing structures. In the wire bonding process at the sixth and seventh stages 700-800, the bond pads 302 can be positioned within an inner region of the die 130 or 180. This inner region of the die 130 or 180 refers to a central area of the die surface. Positioning the bond pads 302 in this central area can improve electrical performance by reducing signal path lengths to the active circuit region 122 or 178. The interconnect structure 102 or 154, which provides the contact pads 104 or 158 as I/O pads at a periphery at a lower portion, can be configured with a width sufficient to accommodate wire bonding requirements (e.g., a width greater than 100 micrometers in some embodiments). Such a width allows the wire bond landing areas (e.g., edge metal segments 510 or 610 of the metal routing structures 502 or 602) and the corresponding top metal segments 506 or 612 to each have a dimension sufficient for reliable bonding, such as at least 50 micrometers in certain non-limiting examples, thereby meeting spatial constraints of a wire bonder for forming electrical connections between the bond pads 302 and the edge metal segments 510 or 610.

In some examples, the method proceeds to an eighth stage 900 from the sixth stage 700. At the eighth stage 900, a molding 902 is formed to encapsulate the metal routing structures 502 while leaving a surface of each top metal segment 506 exposed, resulting in an intermediate wafer structure 906, as illustrated in FIG. 9. The molding 902 covers the edge metal segments 510 of the metal routing structures 502 and the formed electrical connections between the bond pads 302 and the metal routing structures 502, providing mechanical protection and environmental sealing. In some examples, a wafer assembly (e.g., the intermediate wafer structure 706 as illustrated in FIG. 7) is placed into a mold cavity. A thermosetting molding compound, such as EMC, can be injected under heat and pressure. The molding compound can be cured in the mold cavity at an elevated temperature to polymerize and harden, resulting in the molding 902. In some examples, the encapsulation process can utilize transfer molding with solid mold compound pellets, where the solid pellets are melted in a chamber and then transferred under pressure into a mold cavity to encapsulate the metal routing structures and electrical connections. This approach allows for precise control over the molding process and can accommodate a variety of mold compounds, such as epoxy-based materials, to achieve robust mechanical protection and environmental sealing. The use of solid mold compound pellets in transfer molding complements the liquid molding techniques by offering an alternative that may enhance manufacturing flexibility and material consistency. Once fully cured, a molded wafer assembly can be ejected and excess material (flash) can be trimmed, if needed. In other examples, the method proceeds to a ninth stage 1000 from the seventh stage 800. At the ninth stage 1000, a molding 1004 is formed (e.g., in the same or similar manner as described herein with respect to FIG. 9) to encapsulate the metal routing structures 602 while leaving a surface of each top metal segment 612 exposed, resulting in an intermediate wafer structure 1006, as illustrated in FIG. 10. The molding 1004 covers the edge metal segments 610 and the formed electrical connections between the bond pads 302 and the metal routing structures 602, providing mechanical protection and environmental sealing.

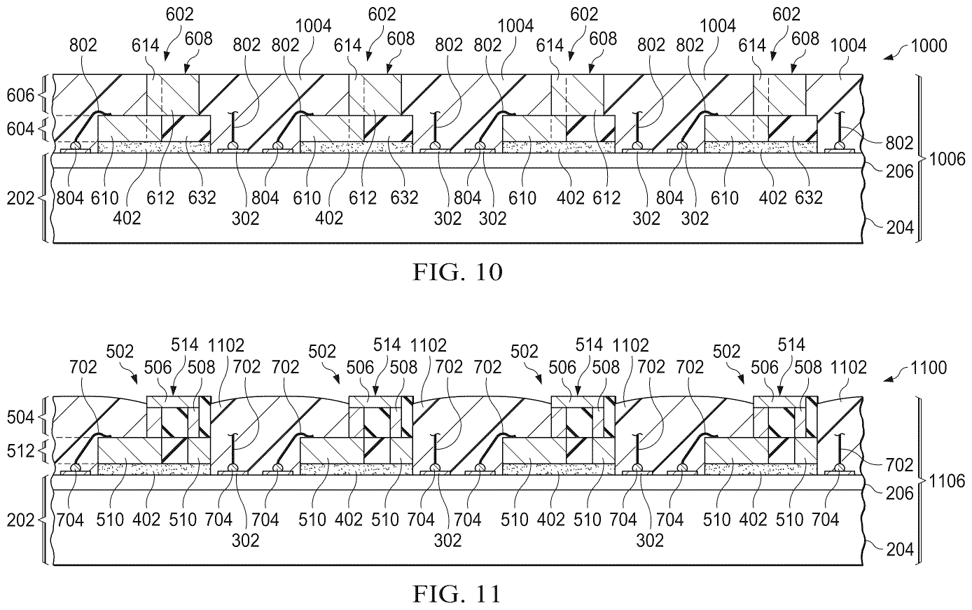

In yet some examples, the method proceeds to a tenth stage 1100 from the sixth stage 700 for liquid molding to provide an intermediate wafer structure 1106, as illustrated in FIG. 11. At the tenth stage 1100, a molding 1102 is formed to encapsulate the metal routing structures 502 while leaving a surface of each top metal segment 506 exposed. The molding 1102 covers the edge metal segments 510 and the formed electrical connections between the bond pads 302 and the metal routing structures 502, providing mechanical protection and environmental sealing. Liquid molding, such as liquid compression molding (LCM) or transfer molding, can be used at the tenth stage 1100 for encapsulation. In liquid compression molding, a preheated liquid molding compound (e.g., a low-viscosity epoxy resin) can be dispensed onto a wafer assembly (e.g., the intermediate wafer structure 706 as illustrated in FIG. 7) before being compressed under a heated press, allowing the resin to flow and fill voids before curing.

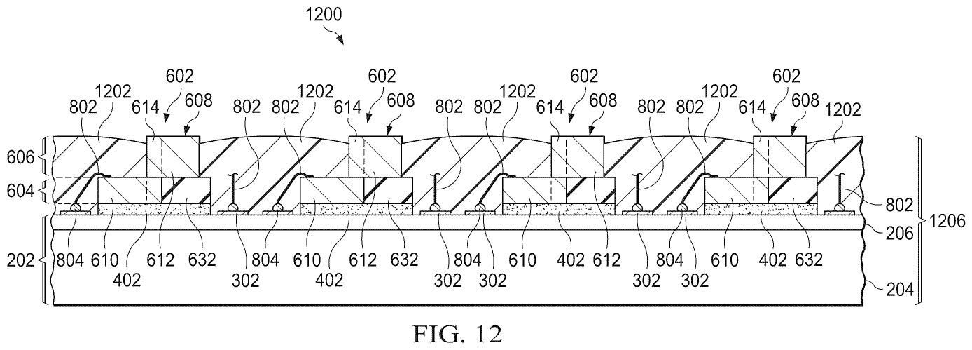

In transfer molding, the liquid molding compound is pre-melted in a chamber and then transferred under pressure into a mold cavity where the transferred molding compound encapsulates the metal routing structures 502. After curing, a molded structure can be released from the mold and undergoes post-molding processes, such as plasma cleaning or deflash processing, to remove unwanted mold residues. In other examples, the method proceeds to an eleventh stage 1200 from the seventh stage 800. At the eleventh stage 1200, a molding 1202 is formed (e.g., in the same or similar manner as described herein with respect to FIG. 11) to encapsulate the metal routing structures 602 while leaving a surface of each top metal segment 612 exposed, resulting in an intermediate wafer structure 1206, as illustrated in FIG. 12. The molding 1202 covers the edge metal segments 610 and the formed electrical connections between the bond pads 302 and the metal routing structures 602, providing mechanical protection and environmental sealing.

In some examples, the method proceeds from the eighth stage 900 or the tenth stage 1100 to a twelfth stage 1300 for singulation. For example, at the twelfth stage 1300, the intermediate wafer structure 906 or the intermediate wafer structure 1106 can be singulated, resulting in semiconductor packages 1306 or 1308, which can be similar to the semiconductor device 100 of FIG. 1A or the semiconductor device 152 of FIG. 1G. The singulation process can be performed using techniques such as wafer dicing, laser cutting, or mechanical sawing. In some implementations, a singulation tool (e.g., a dicing saw) is used to cut along predefined scribe lines to provide semiconductor packages.

In other examples, the method proceeds from the ninth stage 1000 or the eleventh stage 1200 to a thirteenth stage 1400 for singulation. For example, at the thirteenth stage 1400, the intermediate wafer structure 1006 or the intermediate wafer structure 1206 can be singulated into individual semiconductor packages 1406 or 1408, which can be similar to the semiconductor device 100 of FIG. 1A or the semiconductor device 152 of FIG. 1G. The singulation process can be performed using techniques such as described herein. For example, a singulation tool (e.g., a dicing saw) can be used to cut along predefined scribe lines to provide semiconductor packages.

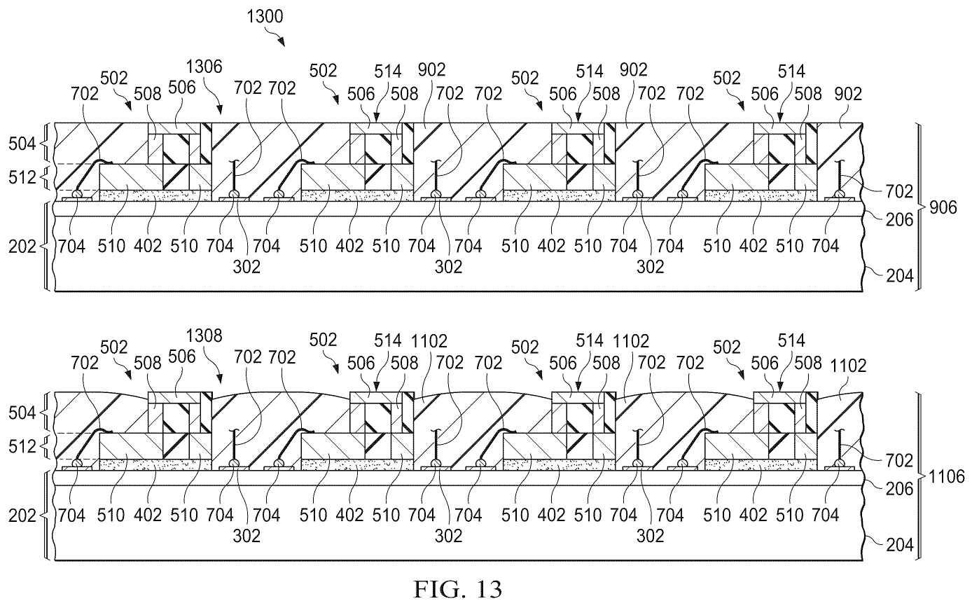

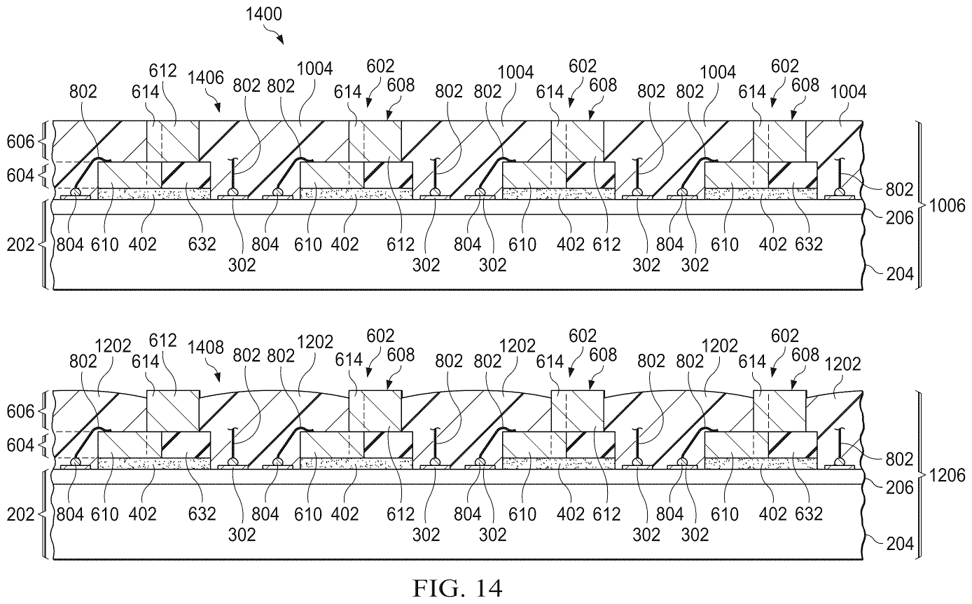

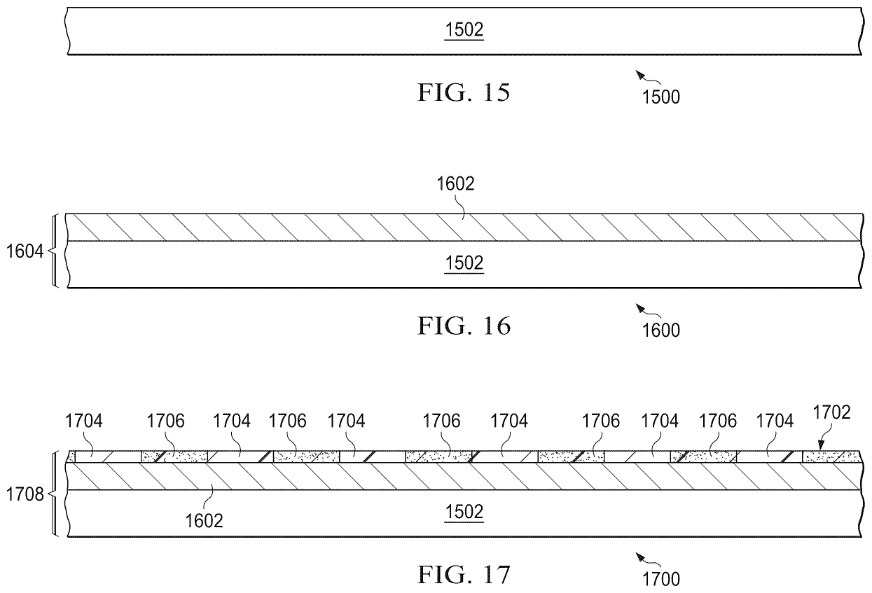

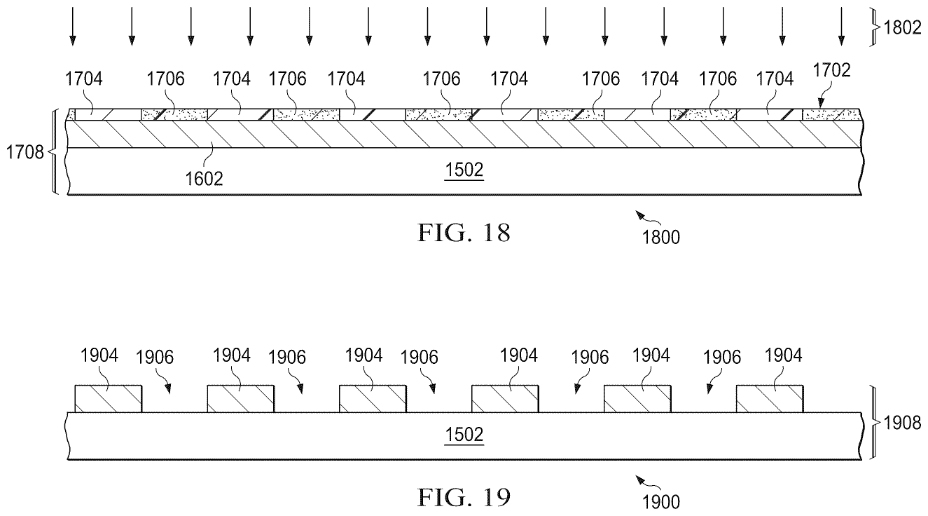

FIGS. 15-23 illustrate stages of a method for fabricating metal routing structures, such as the metal routing structures 602 of FIG. 6 for use in semiconductor device manufacturing (e.g., manufacturing of the semiconductor device 100 of FIG. 1 or the semiconductor package 1406 and/or 1408 of FIG. 14). The fabrication of the metal routing structures can be implemented using routable lead frame (RLF) technology.

As illustrated in FIG. 15, at a first stage 1500, a base substrate 1502 is provided. The base substrate 1502 includes a reinforced material, such as glass-fiber-reinforced epoxy or ABF. The base substrate 1502 is formed through an additive process involving sequential deposition of dielectric layers. The RLF process builds conductive structures layer-by-layer using deposition and patterning. At a second stage 1600, a metal layer 1602 can be deposited onto the base substrate 1502, forming an intermediate structure 1604, as shown in FIG. 16.

For example, at a third stage 1700, a photoresist layer and a photomask 1702 is positioned on the metal layer 1602 for photolithographic patterning, yielding an intermediate structure 1708, as illustrated in FIG. 17. The photomask includes transparent regions 1704 and opaque regions 1706, allowing UV light to selectively expose the metal layer 1602 through the transparent regions 1704 while the opaque regions 1706 shield underlying areas.

At a fourth stage 1800, UV light 1802 is directed through the photomask onto the photoresist layer to alter the solubility of the photoresist layer. The UV light 1802 passes through the transparent regions 1704 of the photomask, exposing corresponding portions of the photoresist layer. For a negative-tone photoresist (e.g., SU-8 or BCB), the exposed regions cross-link and become insoluble, while the unexposed regions remain soluble. For a positive-tone photoresist, the exposed regions degrade and become soluble, leaving the unexposed regions intact. After exposure, the photomask is removed. At a fifth stage 1900, the photoresist layer undergoes development to remove soluble portions, resulting in a patterned photoresist mask on the metal layer 1602. The metal layer 1602 is then etched using the patterned photoresist mask. The etching process removes the metal in the areas not protected by the photoresist, transferring the pattern from the photoresist to the metal layer. After etching, the photoresist mask is stripped away, resulting in an intermediate structure 1908 having first metal segments 1904 that are separated by exposed regions 1906, as illustrated in FIG. 19.

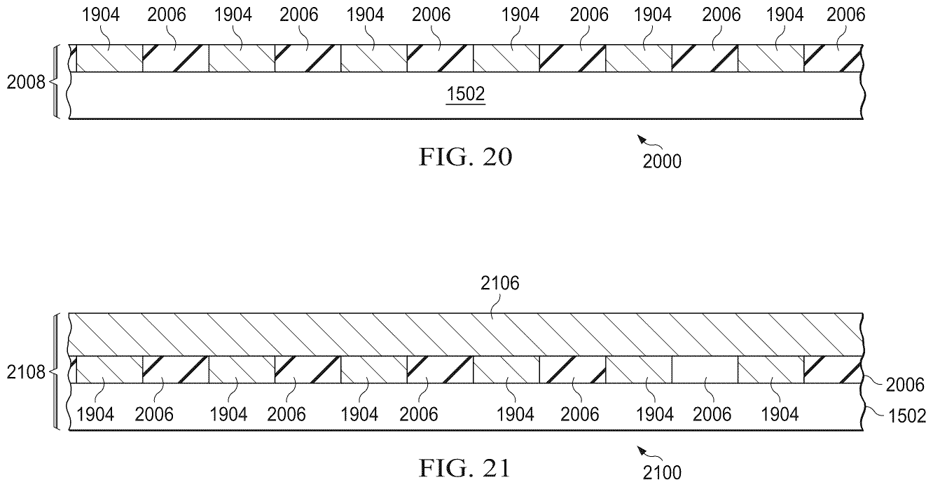

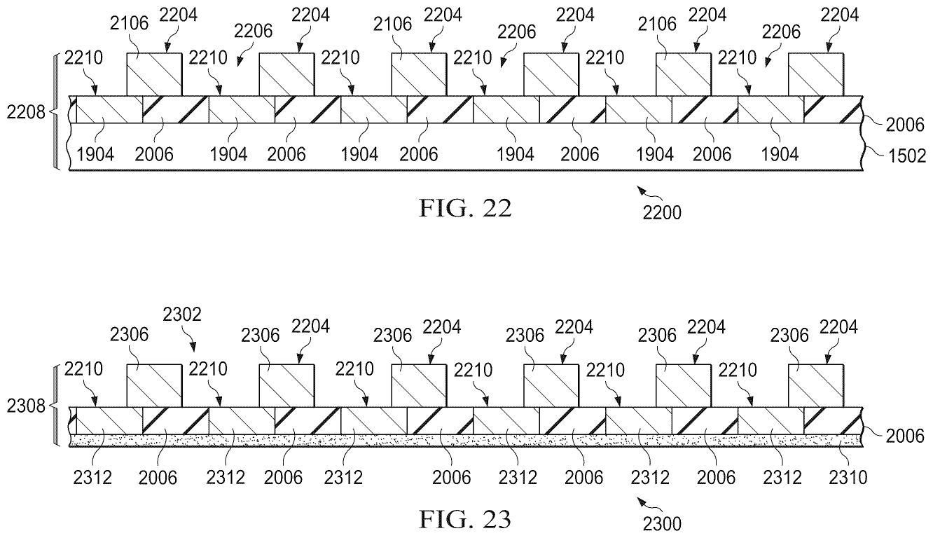

At a sixth stage 2000, a dielectric material 2006 is deposited to fill the exposed regions 1906, yielding an intermediate structure 2008, as shown in FIG. 20. At a seventh stage 2100, a metal layer 2106 is deposited onto the intermediate structure 2008 to cover the dielectric material 2006 deposited in the exposed regions 1906 and to cover the first metal segments 1904, resulting in an intermediate structure 2108, as illustrated in FIG. 21. At an eighth stage 2200, the metal layer 2106 can be patterned in the same or similar manner as described herein to form an intermediate structure 2208 with cavities 2206 that separate second metal segments 2204, as illustrated in FIG. 22.

At a ninth stage 2300, the base substrate 1502 can be removed to expose an underlying metal portion 2210 and an adhesive material can be applied to the underlying metal portion 2210 to form an adhesive layer 2310, resulting in an intermediate structure 2308, as illustrated in FIG. 23. In alternative implementations, the application of the adhesive material to the underlying metal portion 2210 can be omitted at the ninth stage 2300. The intermediate structure 2308 can be singulated along predefined scribe lines, forming individual metal routing structures 2302, as illustrated in FIG. 23. Singulation may employ mechanical sawing, laser dicing, or plasma dicing. The process splits the intermediate structure 2308 into individual metal routing structures 2302, which can correspond to the metal routing structures 602 of FIG. 6. For example, each metal routing structure 2302 includes a top metal segment 2306 (e.g., corresponding to the top metal segment 612 of FIG. 6), an edge metal segment 2312 (e.g., corresponding to the edge metal segment 610 of FIG. 6), and the dielectric material 2006 (e.g., corresponding to dielectric material at the lower portion 604 of the metal routing structures 602 of FIG. 6).

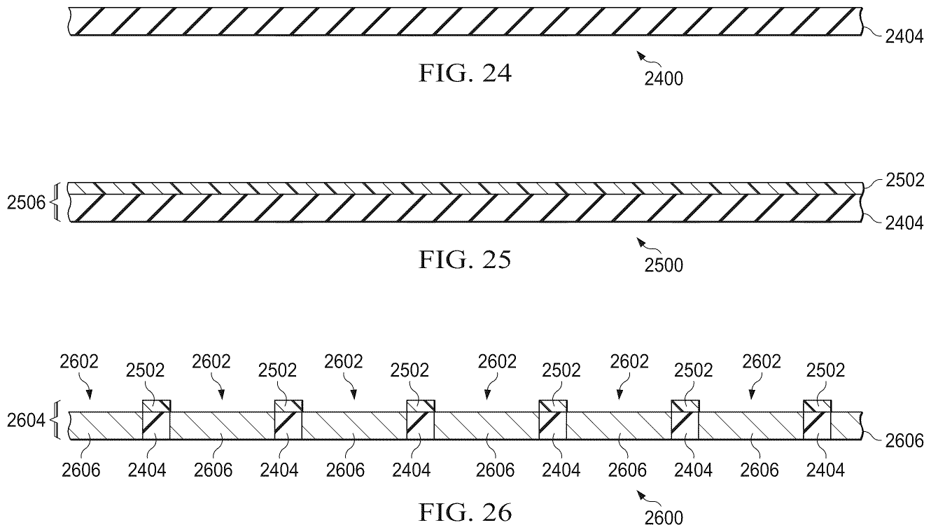

FIGS. 24-34 illustrate stages of a method for fabricating metal routing structures, such as the metal routing structures 502 of FIG. 5 for use in semiconductor device manufacturing (e.g., manufacturing of the semiconductor device 152 of FIG. 1 or one of the semiconductor packages 1306 and/or 1308 of FIG. 13). The fabrication of the metal routing structures can be implemented using laminate or substrate technology.

As illustrated in FIG. 24, at a first stage 2400, a dielectric layer 2404 can be formed. In yet some examples, the dielectric layer can be formed at the first stage 2400. The dielectric layer 2404 can be a reinforced epoxy resin, bismaleimide-triazine (BT), resin, polyamide, or ABF.

At a second stage 2500, a photoresist layer (also known as a photoresist mask layer) 2502 can be formed on the dielectric layer 2404, resulting in an intermediate structure 2506, as illustrated in FIG. 25. In some examples, at the second stage 2500, the photoresist layer 2502 can be exposed to UV light and developed to form a pattern for etching.

At a third stage 2600, the dielectric layer 2404 and the photoresist layer 2502 can be etched to form voids (or etched regions) 2602. A metal material is deposited to fill the voids 2602, resulting in first metal segments 2606. Thus, the metal layer 2606 and dielectric layer 2404 can be within the same plane. In some examples, at the third stage 2600 an intermediate structure 2604, as illustrated in FIG. 26 can be formed. For example, an etching process can be used to selectively remove portions of the dielectric layer 2404 and the photoresist layer 2502. In yet some examples, the dielectric layer 2404 and the photoresist layer 2502 can be etched using a photolithographic patterning process followed by a wet etching or dry etching technique, such as ferric chloride (FeCl₃) or cupric chloride (CuCl₂) for wet etching, or plasma etching.

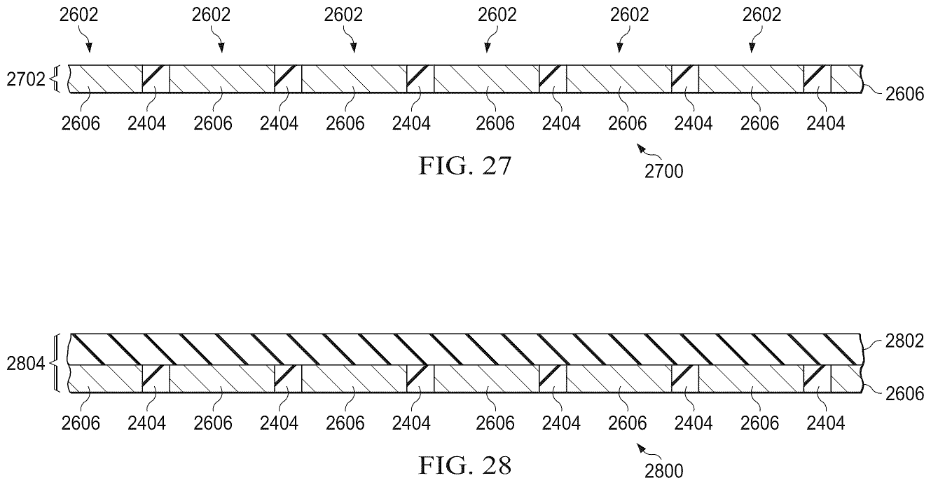

At a fourth stage 2700, remaining photoresist material of the photoresist layer 2502 can be removed (stripped away) to provide an intermediate structure 2702, as illustrated in FIG. 27. For example, a wet stripping solution (e.g., a chemical resist stripper) or plasma ashing can be used to strip away any remaining photoresist material.

At a fifth stage 2800, an insulating material can be applied over the first metal segments 2606, which forms an insulating layer 2802, thereby resulting in an intermediate structure 2804, as illustrated in FIG. 28.

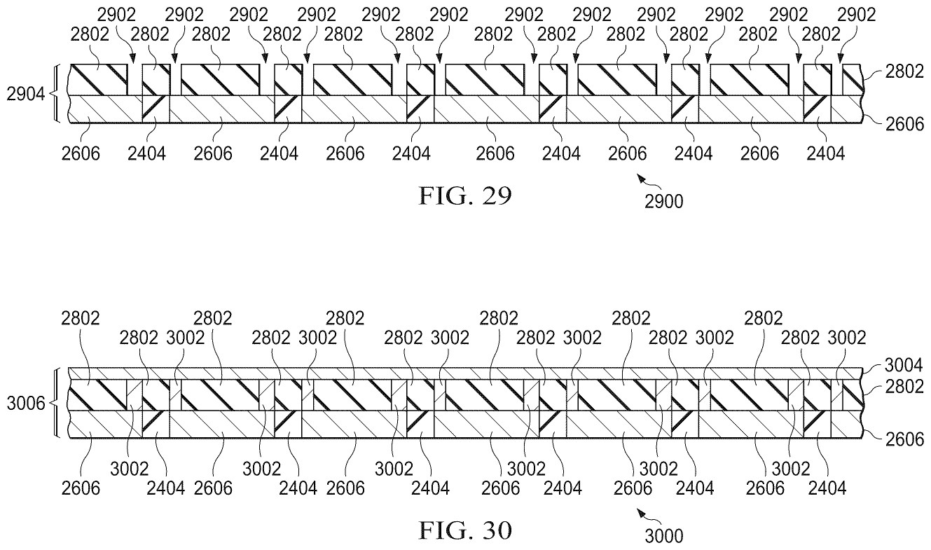

At a sixth stage 2900, openings 2902 are formed in the insulating layer 2802 to expose portions of the first metal segments 2606 that underlies the insulating layer 2802, resulting in an intermediate structure 2904, as illustrated in FIG. 29. For example, portions of the insulating material 2802 can be removed to form the openings 2902 therein to expose first surface portions of the first metal segments 2606. The openings 2902 can be formed using a drilling (e.g., laser or mechanical drilling) or an etching process (e.g., a plasma etching process or chemical etching process).

At a seventh stage 3000, the openings 2902 can be filled with a conductive metal to form metal coupling segments 3002 and the conductive material can be deposited over the insulating material to form a top metal layer 3004, resulting in an intermediate structure 3006, as illustrated in FIG. 30. The metal coupling segments 3002 can be used to establish electrical connectivity between the metal layer 2406 and one or more subsequent metal segments that can be formed. In some examples, electroless copper deposition can be used to create a thin conductive seed layer inside the vias, ensuring uniform adhesion of subsequent metal layers. This can be followed by electroplating, which thickens the metal within the openings 2902 to enhance conductivity and mechanical strength. In yet some examples, sputtering or vacuum deposition techniques can be employed to achieve uniform metal coverage across via surfaces. In some examples, a metal deposition process can be extended to form the top metal layer 3004 over the insulating layer 2802. For instance, if sputtering or vacuum deposition is used, metal can be uniformly deposited, covering both the interior of the openings 2902 and a surface of the insulating layer 2802, thereby forming the top metal layer 3004 in the same step. In other examples, where electroless copper deposition and electroplating are used for via filling, a subsequent metallization step can be performed to deposit the top metal layer 3004 over the insulating layer 2802.

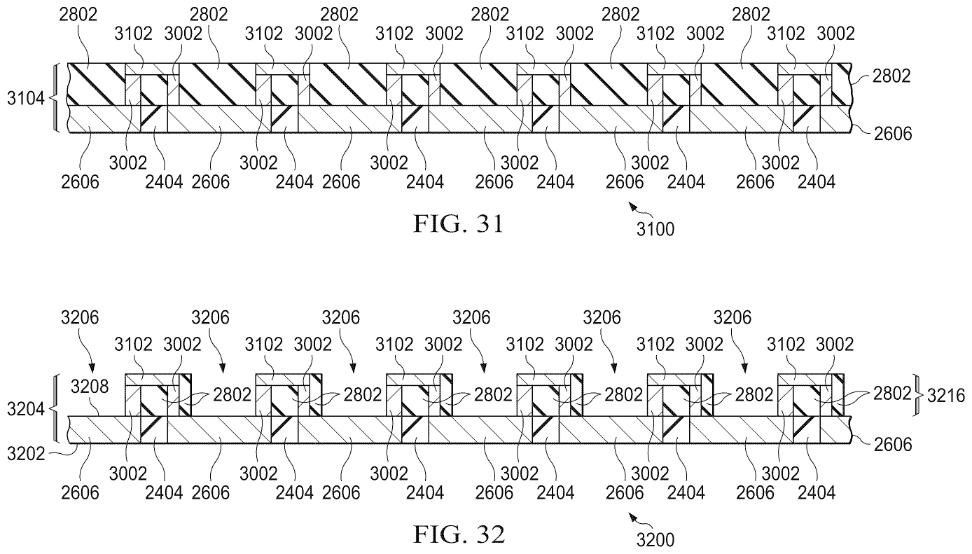

At an eighth stage 3100, as illustrated in FIG. 31, the top metal layer 3004 can be patterned to form second metal segments 3102, followed by the application of the insulating material 2802 to stabilize the structure, resulting in an intermediate structure 3104, as illustrated in FIG. 31. Each of the second metal segments 3102 is coupled via a metal coupling segment 3002 to one of the first metal segments 2606, thereby forming a conductive routing feature, for example, as described herein. In yet some examples, a portion of a respective first metal segment and a portion of a respective second metal segment can define a metal coupling segment.

At a ninth stage 3200, cavities 3206 (or recessed areas) are formed in an upper portion 3216 of the intermediate structure 3104. The recessed areas are void regions where portions of the second metal segments 3102 and an underlying insulating material have been removed, exposing a corresponding second surface portion of the first metal segments 2606, resulting in an intermediate structure 3204, as illustrated in FIG. 32. These recessed areas (the cavities 3206) can be formed using a drilling process (e.g., laser drilling or mechanical drilling) or an etching process (e.g., plasma etching or chemical etching). A lower surface of each recessed area, referred to as a recessed metal surface 3208, corresponds to an exposed underlying section of one of the first metal segments 2606 that was revealed after removal of the overlying insulating layer and portions of the second metal layer segment 3102.

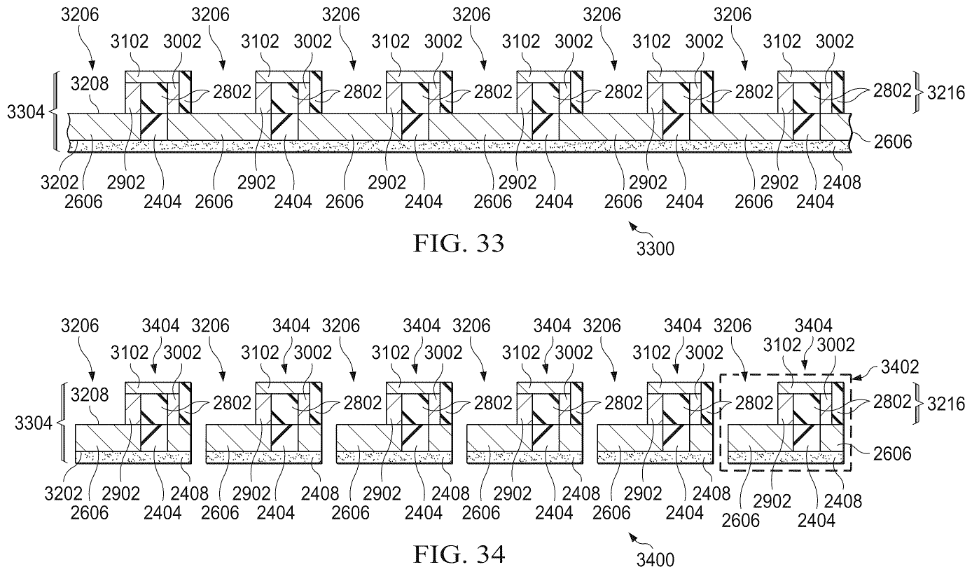

In some examples, at a tenth stage 3300, an adhesive layer 2402 can be formed on the bottom surface 3202, resulting in an intermediate structure 3304, as illustrated in FIG. 33. In yet other examples, the tenth stage 3300 can be omitted and the method can proceed to an eleventh stage 3400.

At the eleventh stage 3400, the intermediate structure 3304 of FIG. 33 (or, in some examples, the intermediate structure 3204 of FIG. 33) undergoes a singulation process, where this structure is cut along predefined dicing streets or scribe lines to form individual metal routing structures 3404, as illustrated in FIG. 34. In some examples, the metal routing structures 3404 correspond to the metal routing structures 502 of FIG. 5. The singulation process can be performed using mechanical sawing, laser dicing, or plasma dicing. For example, the cutting process occurs through the cavities 3206.

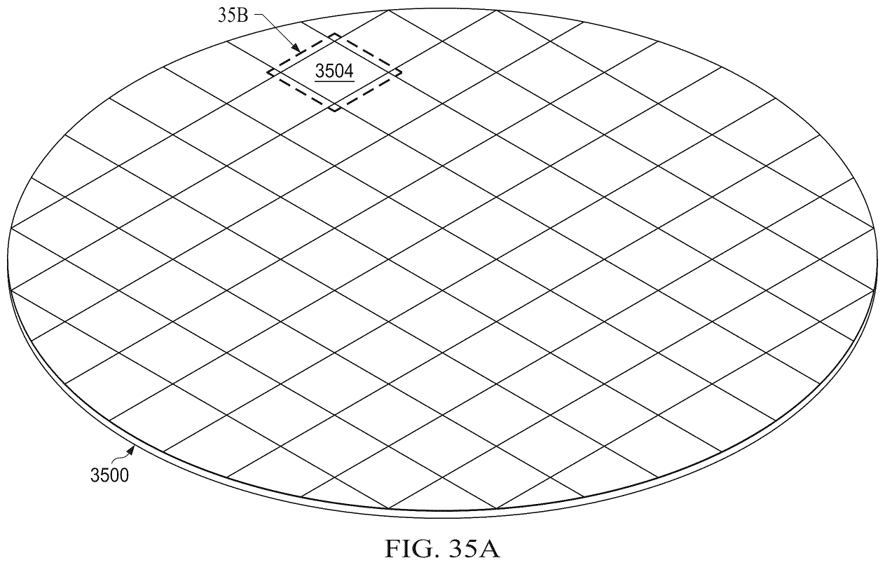

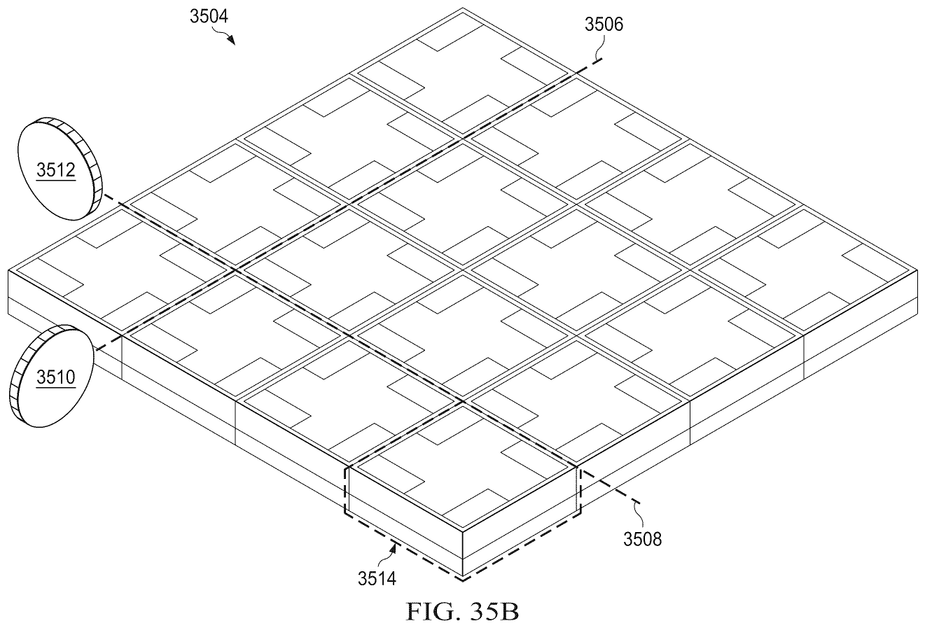

FIG. 35A illustrates a first example of a diagram of a wafer 3500. In some examples, the wafer 3500 can correspond to the intermediate wafer structure 1006 or 1206, as illustrated in FIG. 14. The wafer 3500 represents a stage in the fabrication process prior to singulation, where multiple semiconductor dies (e.g., such as the die 130 of FIG. 1A) and interconnect structures (e.g., such as the interconnect structure 102 of FIG. 1A) are integrated within a wafer. A magnified projection 3504 of a portion of the wafer 3500 illustrates a region containing multiple semiconductor dies with interconnect structures, prior to separation into individual semiconductor packages, such as the semiconductor device 100 of FIGS. 1A-1F. The magnified projection 3504 of the wafer 3500 is illustrated in further detail in FIG. 35B and is referred to as “35B” in FIG. 35A.

As illustrated in FIG. 35B, scribe lines 3506 and 3508 are defined with respect to the wafer 3600. The scribe lines 3506 can be arranged in a first direction and the scribe lines 3508 are arranged in a second direction, which can be perpendicular to the first direction, forming a grid pattern across the wafer 3500. For clarity and brevity purposes, a single scribe line of each of the scribe lines 3506-3508 is illustrated in FIG. 35B. These scribe lines 3506 and 3508 correspond to predefined paths for singulation. When fabrication of semiconductor devices, such as the semiconductor device 100 of FIGS. 1A-1F, is complete, semiconductor dies with corresponding interconnect structures can be singulated from the wafer 3500 using wafer dicing tools, such as a dicing saw or laser cutting tools, to cut along the scribe lines 3506-3508, separating a die and respective interconnect structure into discrete units.

For example, during the singulation process, a first saw operation at 3510 can occur along scribe line 3506, followed by a second saw operation at 3512 along scribe line 3508. This singulation process, which can be implemented as part of the thirteenth stage 1400 as illustrated in FIG. 14, in some examples, separates the wafer 3500 into individual semiconductor packages. Each singulated semiconductor package can include an interconnect structure similar to the interconnect structure 102 of the semiconductor device 100 of FIGS. 1A-1F. As illustrated in FIG. 35B, the singulation process results in a plurality of semiconductor packages, such as a semiconductor package 3514, each containing a die and a corresponding interconnect structure. In some examples, the semiconductor package 3514 corresponds to the semiconductor device 100 of FIGS. 1A-1F.

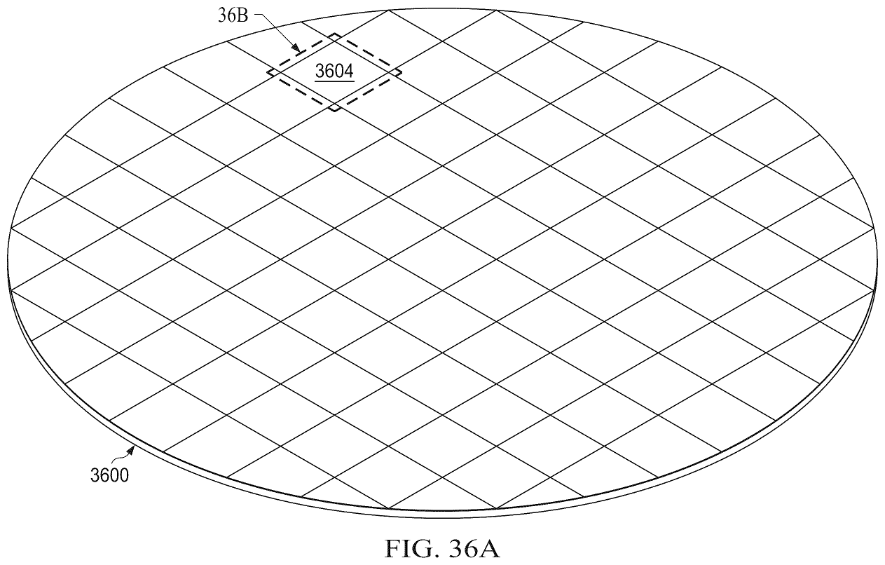

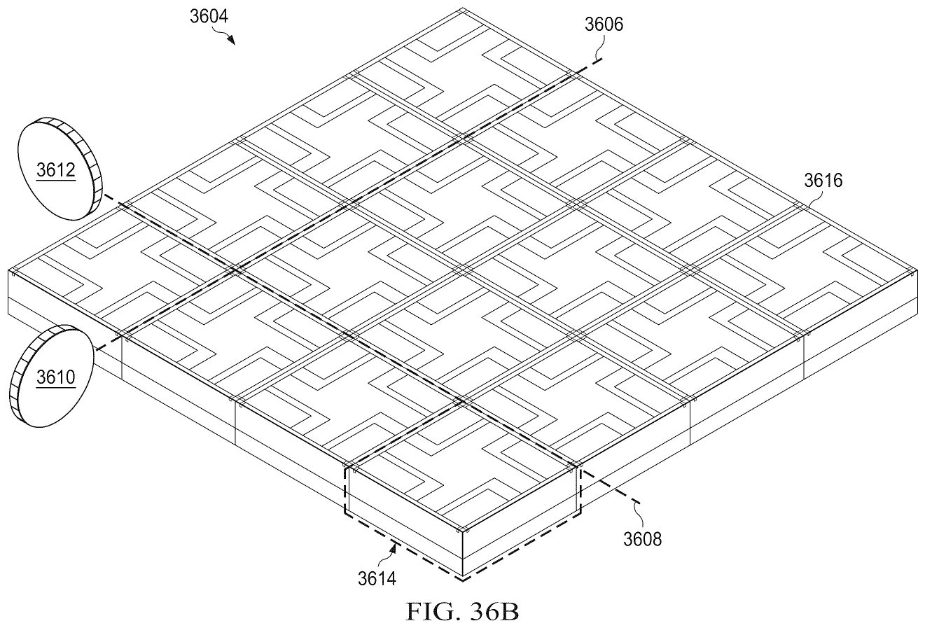

FIG. 36A illustrates a second example of a diagram of a wafer 3600. The wafer 3600 can correspond to the intermediate wafer structure 906 or 1106, as illustrated in FIG. 13. The wafer 3600 represents a stage in the fabrication process prior to singulation, where multiple semiconductor dies (e.g., such as the die 180 of FIG. 1G) and interconnect structures (e.g., such as the interconnect structure 154 of FIG. 1G) are integrated within a wafer. A magnified projection 3604 of a portion of the wafer 3600 illustrates a region containing multiple semiconductor dies with interconnect structures before separation into individual semiconductor packages, such as the semiconductor device 152 of FIGS. 1G-1L. The magnified projection 3604 of the wafer 3600 is illustrated in further detail in FIG. 36B and is referred to as “36B” in FIG. 36A.

As illustrated in FIG. 36B, the wafer 3600 includes scribe lines 3606 and scribe lines 3608 are defined with respect to the wafer 3600. The scribe lines 3606 are arranged in a first direction and scribe lines 3608 are arranged in a second direction, typically perpendicular to the first direction, forming a grid pattern across the wafer 3600. For clarity and brevity, a single scribe line of each of the scribe lines 3606-3608 is illustrated in FIG. 36B. These scribe lines 3606 and 3608 correspond to predefined paths for singulation. Once fabrication of semiconductor devices, such as the semiconductor device 152 of FIGS. 1G-1L, is complete, semiconductor dies with corresponding interconnect structures can be singulated from the wafer 3600. Wafer dicing tools, such as a dicing saw or laser cutting tools, are used to cut along the scribe lines 3606-3608, separating each die and a respective interconnect structure into discrete units.

During the singulation process, saw operations are performed along the scribe lines. A first saw operation occurs at 3610 along the scribe line 3606 in one direction, followed by a second saw operation at 3612 along a perpendicular scribe line (the scribe line 3608). This singulation process, which can be implemented as part of the twelfth stage 1300, as illustrated in FIG. 13, in some examples, separates the wafer 3600 into individual semiconductor packages. Each singulated semiconductor package can include an interconnect structure similar to the interconnect structure 154 of the semiconductor device 152 of FIGS. 1G-1L.

In some examples, the wafer 3600 includes laminate substrate connections 3616, which can be utilized during the fabrication of metal routing structures, such as those described herein. The laminate substrate connections 3616 can be used in examples of metal routing structure fabrication that utilize an electrolytic copper plating process, where an external electrical current is applied to deposit copper onto conductive surfaces, including metal segments, conductive vias, and/or edge metal segments of the metal routing structures, as described herein. For example, the laminate substrate connections 3616 can be used to provide electrical continuity across a laminate, enabling uniform copper deposition by serving as a current pathway during the electroplating process. In some examples, the laminate substrate connections 3616 can be omitted, such as in an electroless plating process. In electroless plating, copper deposition can occur spontaneously on catalytic surfaces without a need for electrical connectivity across a laminate.

In this description, unless otherwise stated, “about,” “approximately” or “substantially” preceding a parameter means being within +/−10 percent of that parameter. Modifications are possible in the described embodiments and other embodiments are possible within the scope of the claims.

What is claimed is:

1. A semiconductor package comprising:
a die;
an interconnect structure attached to the die, the interconnect structure including electrical interfaces, each electrical interface comprising:
a contact pad located at a lower portion of the interconnect structure at a periphery thereof; and
a metal bonding segment located at an upper portion of the interconnect structure relative to the lower portion and in electrical contact with the die and the contact pad.

2. The semiconductor package of claim 1, wherein each electrical interface further comprises: a metal coupling segment extending between the lower and upper portions of the interconnect structure to electrically couple the metal bonding segment to the contact pad.

3. The semiconductor package of claim 2, wherein each electrical interface is a conductive routing feature embedded within a body of the semiconductor package.

4. The semiconductor package of claim 2, further comprising an adhesive material to secure the interconnect structure to the die.

5. The semiconductor package of claim 2, wherein each metal bonding segment is electrically coupled to a die connection by a wire.

6. The semiconductor package of claim 5, wherein the interconnect structure includes a cavity filled with a molding and at least partially surrounded by a dielectric material and the metal coupling segment is at least partially disposed within the dielectric material.

7. The semiconductor package of claim 6, wherein the wire is positioned in the cavity.

8. The semiconductor package of claim 6, wherein the die connection is located on a surface of the die, the die pad being positioned at a bottom of the cavity, the cavity being an open region within the interconnect structure bounded by at least the surface of the die at the bottom.

9. The semiconductor package of claim 1, wherein contact pads of the electrical interfaces are positioned at corners of the interconnect structure.

10. A method comprising:
providing a wafer;
attaching metal routing structures to a surface of the wafer, each metal routing structure comprising conductive routing features that extend through a body of each of the metal routing structures;
forming electrical connections between bonding locations of the wafer and conductive routing features;
encapsulating the attached metal routing structures and the formed electrical connections with a mold while leaving a portion of the conductive routing features exposed; and
singulating the intermediate wafer structure into semiconductor packages.

11. The method of claim 10, wherein each conductive routing feature comprises:
a top metal segment located at an upper portion of a metal routing structure; and
an edge metal segment located at a lower portion of the metal routing structure at a periphery of the metal routing structure and is electrically coupled to the top metal segment.

12. The method of claim 11, wherein the forming comprises bonding each edge metal segment of each metal routing structure to one of the bonding locations using a wire to form the electrical connections.

13. The method of claim 12, wherein metal routing structures neighboring each other define an opening, and each bonding location of the bonding locations is located within the cavity, such that the wire is located in the opening.

14. The method of claim 10, wherein the encapsulating comprises using a molding process to encapsulate the attached metal routing structures and the formed electrical connections, the molding process including one of liquid molding or transfer molding using solid mold compound pellets.

15. The method of claim 10, further comprising:
depositing a first metal layer on a base substrate;
patterning the first metal layer to form first metal segments separated by exposed regions;
depositing a dielectric material to fill the exposed regions;
forming conductive paths through the dielectric material to contact the first metal segments;
depositing a second metal layer over the dielectric material and the first metal segments, wherein the second metal layer electrically couples to the first metal segments via the conductive paths;
patterning the second metal layer to form second metal segments and cavities exposing portions of the first metal segments, thereby providing an intermediate structure; and
singulating the intermediate structure to form the metal routing structures.

16. The method of claim 15, further comprising forming an adhesive layer on a side of the substrate opposite a side on which the metal material is deposited.

17. The method of claim 10, further comprising:
forming first metal segments within a dielectric layer;
depositing an insulating layer over the first metal segments;
forming openings in the insulating material to expose portions of the first metal segments;
filling the openings with a conductive material to form metal coupling segments and depositing a top metal layer over the insulating layer;
patterning the top metal layer to form second metal segments, each second metal segment electrically coupled to a respective first metal segment via a metal coupling segment;
forming cavities in the insulating material to expose portions of the first metal segments, thereby providing an intermediate structure; and
singulating the intermediate structure to form the metal routing structures.

18. The method of claim 17, further comprising forming an adhesive layer on a side of semiconductor material opposite a side on which the conductive metal was deposited.

19. A method comprising:
forming a plurality of metal routing structures, each metal routing structure comprising conductive routing features that extend through a body of each of the metal routing structures;
securing the plurality of metal routing structures to a wafer;
forming electrical connections between bonding locations of the wafer and the conductive routing features;
encapsulating the attached metal routing structures and the formed electrical connections with a mold while leaving a portion of the conductive routing features exposed to provide an intermediate wafer structure; and
singulating the intermediate wafer structure into semiconductor packages, wherein the exposed portion of each conductive routing feature forms a contact pad of a respective semiconductor package.

20. The method of claim 19, wherein each conductive routing feature comprises:
a top metal segment located at an upper portion of a metal routing structure; and
an edge metal segment located at a lower portion of the metal routing structure at a periphery of the metal routing structure and electrically coupled to the top metal segment.
